(19) United States
(12) Patent Application Publication
(10) Pub. No.: US 2007/0045689 A1
(43) Pub. Date: Mar. 1, 2007

(54) Ferroelectric Structures Including Multilayer Lower Electrodes and Multilayer Upper Electrodes, and Methods of Manufacturing Same

(75) Inventors: Ji-Eun Lim, Seoul (KR); Dong-Chul Yoo, Gyeonggi-do (KR); Byoung-Jae Bae, Gyeonggi-do (KR); Dong-Hyun Im, Seoul (KR); Suk-Pil Kim, Gyeonggi-do (KR)

Correspondence Address: MYERS BIGEL SIBLEY & SAJOVEC, PO BOX 37428, RALEIGH, NC, 27627, US

(73) Assignee: Samsung Electronics Co., Ltd., Gyeonggi-do (KR)

(21) Appl. No.: 11/460,177

(22) Filed: Jul. 26, 2006

(30) Foreign Application Priority Data
Aug. 3, 2005 (KR) 10-2005-0071152

(51) Int. Cl. H01L 29/94

(52) U.S. Cl. 257/295

(57) ABSTRACT

In a ferroelectric structure after a first lower electrode film is formed using a first metal nitride, a second lower electrode film is formed on the first lower electrode film using a first metal, a second metal oxide and/or a first alloy. After a ferroelectric layer is formed on the second lower electrode film, a first upper electrode film is formed on the ferroelectric layer using a second alloy. Related devices are also disclosed.

### CROSS-REFERENCE TO RELATED APPLICATION

This application claims the benefit under 35 USC §119 of Korean Patent Application No. 10-2005-0071152, filed on Aug. 3, 2005, the disclosure of which is hereby incorporated herein by reference in its entirety as if set forth fully herein.

### FIELD OF THE INVENTION

This invention relates to ferroelectric structures and methods of forming ferroelectric structures.

### BACKGROUND OF THE INVENTION

Semiconductor memory devices are generally divided into volatile semiconductor memory devices, such as dynamic random access memory (DRAM) devices or static random access memory (SRAM) devices, and nonvolatile semiconductor memory devices, such as erasable programmable read only memory (EPROM) devices, electrically erasable programmable read only memory (EEPROM) or flash memory devices. The volatile semiconductor memory devices lose data stored therein when power is off whereas the nonvolatile semiconductor memory devices can maintain data stored therein even though power is off.

A ferroelectric random access memory (FRAM) device can have a volatile characteristic of a RAM device and simultaneously can have a nonvolatile characteristic of a ROM device. Additionally, the FRAM device may be operated with a voltage lower than that of the EPROM device or the EEPROM device, and data stored in the FRAM device may be maintained for a long time.

Ferroelectric materials, such as PZT [(Pb, Zr)TiO₃], SBT (SrBi₂Ta₂O₉) or BLT [(Bi, La)TiO₃] have been developed for the FRAM device. The ferroelectric material maintains a polarization generated by an applied electric field therein after the applied electric field is removed. An orientation of the polarization in the ferroelectric material can vary in accordance with a direction of an applied electric field.

Methods of manufacturing a ferroelectric capacitor using a ferroelectric material is disclosed at Korean Laid-Open Patent Publication No. 1998-28587, Korean Laid-Open Patent Publication No. 2003-45631, Japanese Laid-Open Patent Publication No. 2002-270785, U.S. Pat. No. 6,351,006 to Yamakawa et al. and U.S. Pat. No. 6,194,228 to Fujiki et al.

FIG. 1 is a cross-sectional view illustrating a conventional ferroelectric capacitor described by the above-cited Korean Laid-Open Patent Publication No. 2003-45631.

Referring to FIG. 1, a conventional ferroelectric capacitor 60 is formed on a semiconductor substrate 5 having a thermal oxide layer 10. The conventional ferroelectric capacitor 60 includes a lower electrode 25, a ferroelectric layer 45 and an upper electrode 57.

The lower electrode 25 has a first iridium oxide layer 15 formed on the thermal oxide layer 10, and a platinum layer 20 formed on the first iridium oxide layer 15. The lower electrode 25 has a size smaller than that of the thermal oxide layer 10.

The ferroelectric layer 45 includes a first PZT-based material layer 30, a second PZT-based material layer 35 and a third PZT-based material layer 40 sequentially formed on the platinum layer 20. The first to the third PZT-based material layers 30, 35 and 40 are formed by spin coating processes and/or thermal decomposition processes. The ferroelectric layer 45 has a size smaller than that of the lower electrode 25.

The upper electrode 57 includes a strontium ruthenium oxide (SRO) layer 50 and a second iridium oxide layer 55 successively formed on the ferroelectric layer 45. The strontium ruthenium oxide (SRO) layer 50 and the second iridium oxide layer 55 have sizes the same as that of the ferroelectric layer 45. The strontium ruthenium oxide (SRO) layer 50 and the second iridium oxide layer 55 are formed by sputtering processes. The upper electrode 57 is thermally treated at a temperature of about 600° C. for about one minute in order to improve crystallization of ingredients in the strontium ruthenium oxide (SRO) layer 50 so as to cure damage to the second iridium oxide layer 55.

FIG. 2 is a graph showing variations of stresses generated in the conventional ferroelectric capacitor 60 during a thermal treatment of the conventional ferroelectric capacitor 60. In FIG. 2, “O” denotes a variation of a stress generated between the second iridium oxide layer 55 and the ferroelectric layer 45, and “Δ” indicates a variation of a stress generated between the second iridium oxide layer and the strontium ruthenium oxide layer 50.

In the conventional ferroelectric capacitor 60, a high compressive stress may be applied to the second iridium oxide layer 55 when the upper electrode 57 is thermally treated at a temperature of about 600° C. as shown in FIG. 2. Since the compressive stress is generated in the second iridium oxide layer 55, relatively large tensile stresses may be applied to the strontium ruthenium oxide layer 50 and the ferroelectric layer 45, respectively. When the tensile stresses are generated in the strontium ruthenium oxide layer 50 and the ferroelectric layer 45, defects may be generated between the strontium ruthenium oxide layer 50 and the ferroelectric layer 45 by diffusion of oxygen vacancies, thereby forming an interfacial layer having little or no ferroelectric characteristics between the ferroelectric layer 45 and the strontium ruthenium oxide layer 50. This interfacial layer is sometimes referred to as a “dead layer.” When the dead layer is generated between the ferroelectric layer 45 and the strontium ruthenium oxide layer 50, the ferroelectric capacitor 60 may have deteriorated ferroelectric characteristics, such as a decrease of fatigue resistance, a reduction of data retention and/or a reduction of polarization retention. Additionally, the ferroelectric capacitor 60 may have poor electrical characteristics because a leakage current through the ferroelectric later 45 may increase due to the dead layer.

### SUMMARY OF THE INVENTION

According to some embodiments of the present invention, there is provided a ferroelectric structure including a lower electrode, a ferroelectric layer on the lower electrode and an upper electrode on the ferroelectric layer. The lower electrode has a first lower electrode film and a second lower electrode film thereon. The first lower electrode film includes a first metal nitride. The second lower electrode film includes a first metal, a first metal oxide and/or a first alloy. The upper electrode has a first upper electrode film including a second metal oxide and a second upper electrode film including a second alloy thereon.

In an example embodiment of the present invention, the first lower electrode film may include titanium nitride, aluminum nitride, titanium aluminum nitride, tantalum nitride, tungsten nitride, titanium silicon nitride or tantalum silicon nitride. These can be used alone or in a mixture thereof.

In an example embodiment of the present invention, the second lower electrode film may include iridium, platinum, ruthenium, palladium, iridium oxide, ruthenium oxide, strontium ruthenium oxide, or an alloy of iridium and ruthenium. These can be used alone or in a mixture thereof.

In an example embodiment of the present invention, the second lower electrode film may have a double layer structure that includes the first metal and the first metal oxide.

In an example embodiment of the present invention, the first metal oxide and the first alloy may be substantially the same as the second metal oxide and the second alloy, respectively.

In an example embodiment of the present invention, the ferroelectric layer may include BaTiO₃, PZT, SBT, BLT, PLZT and/or BST.

In an example embodiment of the present invention, the first upper electrode film may include indium tin oxide, iridium oxide, strontium ruthenium oxide, strontium titanium oxide, lanthanum nickel oxide or calcium ruthenium oxide. These can be used alone or in a mixture thereof.

In an example embodiment of the present invention, the second upper electrode film may include an alloy of iridium and ruthenium, an alloy of iridium and platinum, an alloy of iridium and palladium, an alloy of ruthenium and platinum, an alloy of ruthenium and palladium, or an alloy of platinum and palladium. These can be used alone or in a mixture thereof.

In an example embodiment of the present invention, the second upper electrode film may include about 30 to about 50 percent by weight of iridium and about 50 to about 70 percent by weight of ruthenium. Alternatively, the second upper electrode film may include iridium and ruthenium by a weight ratio of about 1.0:1.0 to about 1.0:1.4.

In an example embodiment of the present invention, the ferroelectric structure may further include an adhesion layer beneath the first lower electrode film. The adhesion layer may include a second metal or a second metal nitride. For example, the adhesion layer may include titanium, tantalum, aluminum, tungsten, titanium nitride, tantalum nitride, aluminum nitride or tungsten nitride. These can be used alone or in a mixture thereof.

According to other embodiments of the present invention, there is provided a ferroelectric structure having a lower electrode, a ferroelectric layer on the lower electrode and an upper electrode on the ferroelectric layer. The lower electrode includes titanium aluminum nitride and iridium. The ferroelectric layer includes PZT formed by a metal organic chemical vapor deposition (MOCVD) process. The upper electrode includes strontium ruthenium oxide and an alloy including about 30 to about 50 percent by weight of iridium and about 50 to about 70 percent by weight of ruthenium.

In an example embodiment of the present invention, the lower electrode may have a first lower electrode film and a second lower electrode film on the first lower electrode film. The first lower electrode film may include titanium aluminum nitride and the second lower electrode film may include iridium.

In an example embodiment of the present invention, the ferroelectric structure may further include an adhesion layer beneath the first lower electrode film. The adhesion layer may include titanium.

In an example embodiment of the present invention, the upper electrode may include a first upper electrode film on the ferroelectric layer and a second upper electrode film on the first upper electrode film. The first upper electrode film may include strontium ruthenium oxide and the second upper electrode film may include an alloy of iridium and ruthenium.

According to still other embodiments of the present invention, there is provided a ferroelectric capacitor having a lower structure on a substrate, a lower electrode electrically connected to the lower structure, a ferroelectric layer pattern on the lower electrode, and an upper electrode on the ferroelectric layer pattern. The lower electrode has a first lower electrode film pattern including a first metal nitride and a second lower electrode film pattern including a first metal, a first metal oxide and/or a first alloy. The upper electrode has a first upper electrode film pattern including a second metal oxide and a second upper electrode film pattern including a second alloy.

In an example embodiment of the present invention, the second lower electrode film pattern may have a double layer structure that includes the first metal and the first metal oxide.

In an example embodiment of the present invention, the ferroelectric capacitor may further include an insulation structure covering the lower structure and an adhesion layer pattern between the insulation structure and the first lower electrode film pattern. The adhesion layer pattern may include titanium, tantalum, aluminum, tungsten, titanium nitride, tantalum nitride, aluminum nitride and/or tungsten nitride.

According to still other embodiments of the present invention, there is provided a ferroelectric capacitor having a lower structure on a substrate, a lower electrode electrically connected to the lower structure, a ferroelectric layer pattern on the lower electrode, and an upper electrode on the ferroelectric layer pattern. The lower electrode includes titanium aluminum nitride and iridium. The ferroelectric layer pattern includes PZT formed by a MOCVD process. The upper electrode includes strontium ruthenium oxide and an alloy that contains about 30 to about 50 percent by weight of iridium and about 50 to about 70 percent by weight of ruthenium.

In an example embodiment of the present invention, the lower electrode may include a first lower electrode film pattern electrically connected to the lower structure, and a second lower electrode film pattern on the first lower electrode film pattern. The first lower electrode film pattern may include titanium aluminum nitride. The second lower electrode film pattern may include iridium.

In an example embodiment of the present invention, the ferroelectric capacitor may further include an insulation structure covering the lower structure, and an adhesion layer pattern between the insulation structure and the first lower electrode film pattern. The adhesion layer pattern may include titanium.

In an example embodiment of the present invention, the upper electrode may include a first upper electrode film pattern on the ferroelectric layer pattern, and a second upper electrode film pattern on the first upper electrode film pattern. The first upper electrode film pattern may include strontium ruthenium oxide. The second upper electrode film pattern may include an alloy of iridium and ruthenium.

According to still other embodiments of the present invention, there is provided a semiconductor device having a substrate including a contact region, at least one insulation layer on the substrate, at least one pad electrically connected to the contact region through the insulation layer, a lower electrode on the pad and the insulation layer, a ferroelectric layer pattern on the lower electrode, and an upper electrode on the ferroelectric layer pattern. The lower electrode has a first lower electrode film pattern including a first metal nitride, and a second lower electrode film pattern including a first metal, a first metal oxide and/or a first alloy. The upper electrode has a first upper electrode film pattern including a second metal oxide and a second upper electrode film pattern including a second alloy.

In an example embodiment of the present invention, the semiconductor device may further include an adhesion layer pattern between the insulation layer and the first lower electrode film pattern. The adhesion layer pattern may include a second metal and/or a second metal nitride.

According to still other embodiments of the present invention, there are provided methods of forming ferroelectric structures. A first lower electrode film is formed using a first metal oxide. A second lower electrode film is formed on the first lower electrode film using a first metal, a first metal oxide and/or a first alloy. A ferroelectric layer is formed on the second lower electrode film. A first upper electrode film is formed on the ferroelectric layer using a second metal oxide. A second upper electrode film is formed on the first upper electrode film using a second alloy.

In an example embodiment of the present invention, the first lower electrode film may be formed by an electron-beam (E-beam) evaporation process, a sputtering process, a chemical vapor deposition (CVD) process, an atomic layer deposition (ALD) process and/or a pulse laser deposition (PLD) process.

In an example embodiment of the present invention, the ferroelectric layer may be formed by a sol-gel process, a MOCVD process, an ALD process, a liquid phase epitaxy process and/or a PLD process.

In an example embodiment of the present invention, the first upper electrode film may be formed by an E-beam evaporation process, a sputtering process, a CVD process, an ALD process and/or a PLD process.

In an example embodiment of the present invention, the second upper electrode film may be formed by a sputtering process.

In an example embodiment of the present invention, the second upper electrode film may be formed by simultaneously sputtering iridium and ruthenium onto the first upper electrode film from an iridium target and a ruthenium target.

In an example embodiment of the present invention, the second upper electrode film may be formed by sputtering an alloy of iridium and ruthenium onto the first upper electrode film from a target including iridium and ruthenium.

In an example embodiment of the present invention, the first and the second upper electrode films may be thermally treated. For example, the first and the second upper electrode films may be thermally treated at about 500° C. to about 700° C. for about 30 seconds to about 2 minutes under an atmosphere that includes an oxygen gas, a nitrogen gas or a mixture gas of oxygen and nitrogen.

According to still other embodiments of the present invention, there are provided methods of forming ferroelectric capacitors. A lower structure is formed on a substrate. A first lower electrode film is formed to be electrically connected to the lower electrode using a first metal nitride. A second lower electrode film is formed on the first lower electrode film using a first metal, a first metal oxide and/or a first alloy. A ferroelectric layer is formed on the second lower electrode film. A first upper electrode film is formed on the ferroelectric layer using a second metal oxide. A second upper electrode film is formed on the first upper electrode film using a second alloy. The second upper electrode film, the first upper electrode film, the ferroelectric layer, the second lower electrode film and the first lower electrode film are etched to form a lower electrode, a ferroelectric layer pattern and an upper electrode.

In an example embodiment of the present invention, the second upper electrode film may be formed by simultaneously sputtering iridium and ruthenium onto the first upper electrode film from an iridium target and a ruthenium target.

In an example embodiment of the present invention, the second upper electrode film may be formed by sputtering an alloy of iridium and ruthenium onto the first upper electrode film from a target including the alloy of iridium and ruthenium.

In an example embodiment of the present invention, the first and the second upper electrode films may be thermally treated by a rapid thermal process.

According to still other embodiments of the present invention, there are provided methods of manufacturing semiconductor devices. A contact region is formed on a substrate. At least one insulation layer is formed on the substrate. At least one pad is formed to be electrically connected to the contact region through the insulation layer. A first lower electrode film is formed on the pad and the insulation layer using a first metal nitride. A second lower electrode film is formed on the first lower electrode film using a first metal, a first metal oxide and/or a first alloy. A ferroelectric layer is formed on the second lower electrode film. A first upper electrode film is formed on the ferroelectric layer using a second metal oxide. A second upper electrode film is formed on the first upper electrode film using a second alloy. The second upper electrode film, the first upper electrode film, the ferroelectric layer, the second lower electrode film and the first lower electrode film are etched to form a lower electrode, a ferroelectric layer pattern and an upper electrode.

According to some embodiments of the present invention, a first upper electrode film and a second upper electrode film are thermally treated after the first upper electrode film is formed using metal oxide and the second upper electrode film is formed using an alloy. Thus, a ferroelectric structure including the first and the second upper electrode films according to some embodiments of the invention may have enhanced electrical and ferroelectric characteristics such as improved polarization retention, data retention and/or fatigue resistance. As a result, a ferroelectric capacitor including the ferroelectric structure according to some embodiments of the invention may also have improved electrical and ferroelectric characteristics. Additionally, the ferroelectric capacitor may have a sidewall inclined by a high angle of about 80° to about 90° because etching by-product such as ruthenium oxide (RuO₄) may be generated by an etching process for the second upper electrode film when the second upper electrode film includes the alloy of iridium and ruthenium, according to some embodiments of the invention. Therefore, the ferroelectric capacitor may have increased effective area so that the ferroelectric capacitor may have improved data sensing margin. Furthermore, a semiconductor device including the ferroelectric capacitor may also have enhanced electrical and ferroelectric characteristics when the ferroelectric capacitor is employed in the semiconductor device.

### BRIEF DESCRIPTION OF THE DRAWINGS

The above and other features and advantages of the present invention will become more apparent by describing in detailed example embodiments thereof with reference to the accompanying drawings, in which:

FIG. 1 is a cross-sectional view illustrating a conventional ferroelectric capacitor;

FIG. 2 is a graph showing variations of stresses generated in the conventional ferroelectric capacitor during a thermal treatment of the conventional ferroelectric capacitor;

FIG. 3 is a cross-sectional view illustrating a ferroelectric structure in accordance with an example embodiment of the present invention;

FIG. 4 is a cross-sectional view illustrating a ferroelectric structure in accordance with an example embodiment of the present invention;

FIG. 5 is a cross-sectional view illustrating a ferroelectric capacitor in accordance with an example embodiment of the present invention;

FIG. 6 is a flow chart illustrating methods of forming a ferroelectric capacitor in accordance with example embodiments of the present invention;

FIGS. 7 to 10 are cross-sectional views illustrating a method of forming a ferroelectric capacitor in FIG. 6;

FIG. 11 is a cross-sectional view illustrating a ferroelectric capacitor in accordance with an example embodiment of the present invention;

FIGS. 12 to 14 are cross-sectional views illustrating a method of forming a ferroelectric capacitor in FIG. 11;

FIG. 15 is a graph showing a variation of a stress generated between a first upper electrode film and a second upper electrode film of a ferroelectric capacitor according to Example 1;

FIG. 16 is a graph showing variations of stresses generated between first upper electrode films and second upper electrode films of ferroelectric capacitors according to Example 1 and Comparative Example 1;

FIG. 17 is an electron microscopic picture illustrating a cross-sectional view of a ferroelectric capacitor according to Comparative Example 1;

FIG. 18 is a graph showing a P-V hysteresis of a ferroelectric capacitor according to Comparative Example 1;

FIG. 19 is a graph showing a P-V hysteresis of a ferroelectric capacitor according to Comparative Example 2;

FIG. 20 is a graph showing P-V hysteresis of ferroelectric capacitors according to Example 1 and Comparative Example 1;

FIG. 21 is a graph showing maximum and minimum polarization values of ferroelectric capacitors according to Example 1 and Comparative Example 1;

FIG. 22 is a graph showing 2Pr values of ferroelectric capacitors according to Example 1 and Comparative Example 1;

FIG. 23 is a graph showing a polarization variation of a ferroelectric capacitor according to Example 1;

FIG. 24 is a graph showing a variation of a P-V hysteresis of a ferroelectric capacitor according to Example 1;

FIG. 25 is a graph showing a polarization variation of a ferroelectric capacitor according to Comparative Example 1;

FIG. 26 is a graph showing a polarization variation of a ferroelectric capacitor according to Example 1;

FIG. 27 is a cross-sectional view illustrating a semiconductor device in accordance with an example embodiment of the present invention; and

FIGS. 28 to 30 are cross-sectional views illustrating a method of manufacturing a semiconductor device in accordance with an example embodiment of the present invention.

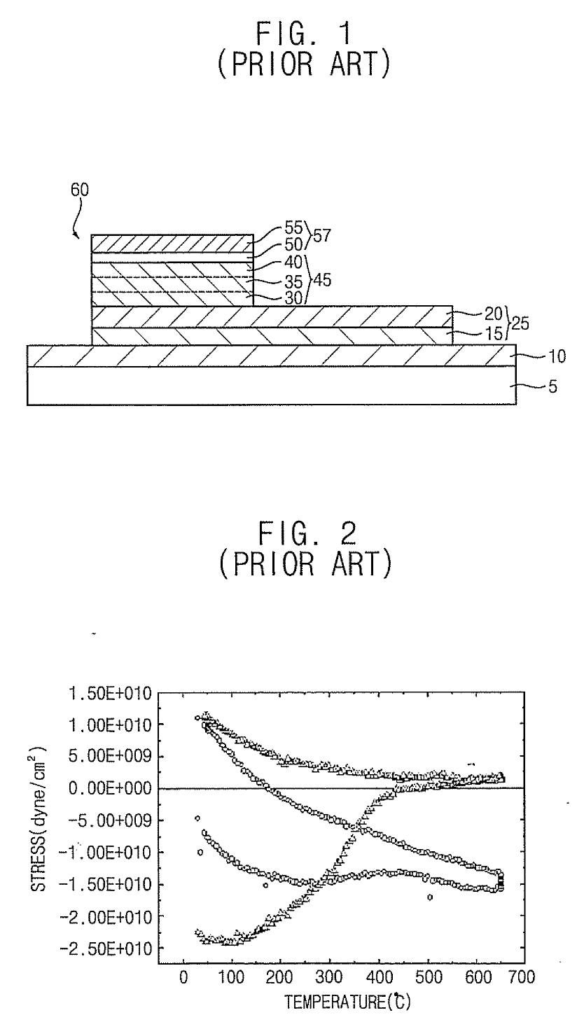

### DETAILED DESCRIPTION

The present invention is described more fully hereinafter with reference to the accompanying drawings, in which example embodiments of the invention are shown. The present invention may, however, be embodied in many different forms and should not be construed as limited to the example embodiments set forth herein. Rather, these example embodiments are provided so that this disclosure will be thorough and complete, and will fully convey the scope of the present invention to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present Like numbers refer to like elements throughout. As used herein, the term “and/or” includes any and all combinations (mixtures) of one or more of the associated listed items and may be abbreviated as “/”.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The structure and/or the device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments of the present invention are described herein with reference to cross-sectional illustrations that are schematic illustrations of idealized embodiments (and intermediate structures) of the present invention. As such, variations from the shapes of the illustrations as a result, for example, of manufacturing techniques and/or tolerances, are to be expected. Thus, example embodiments of the present invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present invention.

It should also be noted that in some alternate implementations, the functions/acts noted in the blocks may occur out of the order noted in the flow charts. For example, two blocks shown in succession may in fact be executed substantially concurrently or the blocks may sometimes be executed in the reverse order, depending upon the functionality/acts involved. Moreover, the functionality of a given block of the flow charts may be separated into multiple blocks and/or the functionality of two or more blocks of the flow charts may be at least partially integrated.

Unless otherwise defined, all terms (including technical and scientific terms) used herein have the same meaning as commonly understood by one of ordinary skills in the art to which the present invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Ferroelectric Structures and Manufacturing Methods Thereof

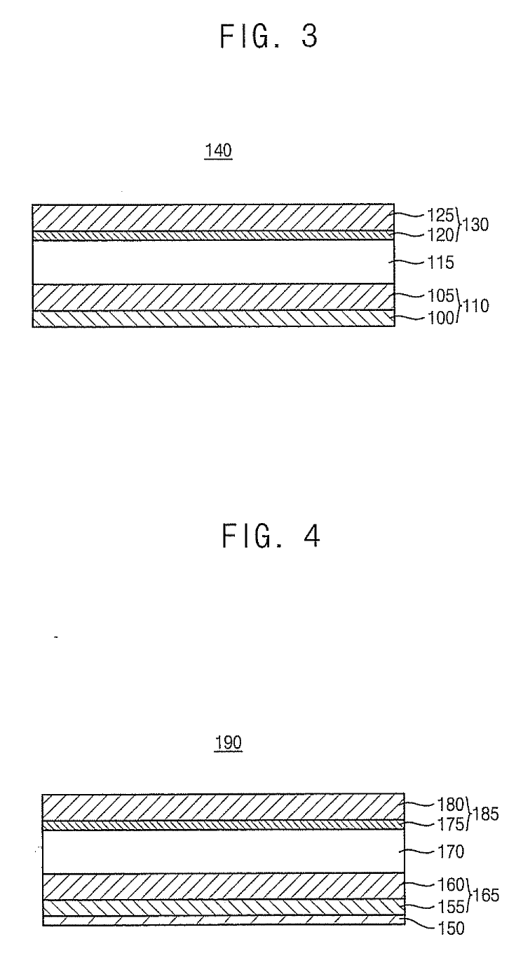

FIG. 3 is a cross-sectional view illustrating a ferroelectric structure in accordance with an example embodiment of the present invention.

Referring to FIG. 3, a ferroelectric structure 140 includes a lower electrode 110, a ferroelectric layer 115 on the lower electrode 110 and an upper electrode 130 on the ferroelectric layer 115.

In one example embodiment of the present invention, the lower electrode 110 may be provided directly on a substrate (not shown) such as a silicon wafer, a single crystalline metal oxide substrate, a silicon-on-insulator (SOI) substrate and/or another substrate.

In another example embodiment of the present invention, the lower electrode 110 may be provided on an insulation structure and/or one or more other structures disposed on the substrate. The insulation structure may include an oxide, a nitride, an oxynitride, etc.

In still another example embodiment of the present invention, the lower electrode 110 may be provided on a lower structure disposed on the substrate. The lower structure may include a contact region, a pad, a plug, a conductive pattern, a conductive wiring and/or a transistor. The lower electrode 110 may be directly on the lower structure or may be electrically connected to the lower structure.

The lower electrode 110 includes a first lower electrode film 100 and a second lower electrode film 105.

The first lower electrode film 100 may include a first metal nitride. For example, the first lower electrode film 100 includes titanium nitride (TiN), aluminum nitride (AlN), titanium aluminum nitride (TiAlN), tungsten nitride (WN), tantalum nitride (TaN), titanium silicon nitride (TiSiN) and/or tantalum silicon nitride (TaSiN), etc. These can be used alone or in a mixture thereof. The first lower electrode film 100 may have a thickness of about 50 to about 500 Å. Additionally, the first lower electrode film 100 may be formed by an electron-beam (E-beam) evaporation process, a sputtering process, a chemical vapor deposition (CVD) process, an atomic layer deposition (ALD) process and/or a pulse laser deposition (PLD) process. In an example embodiment of the present invention, the first lower electrode film 110 may be formed using titanium aluminum nitride by the sputtering process.

The second lower electrode film 105 is on the first lower electrode film 100.

In one example embodiment of the present invention, the second lower electrode film 105 may include a first metal, a first alloy and/or a first metal oxide. As used herein, an “alloy” means a mixture of two or more metallic elements or of metallic and non-metallic elements. For example, the second lower electrode film 105 includes iridium (Ir), ruthenium (Ru), platinum (Pt), palladium (Pd), iridium oxide (IrO₂), ruthenium oxide (RuO₃), strontium ruthenium oxide (SrRuO₃; SRO), an alloy of iridium and/or ruthenium (IrₓRu₁₋ₓ), etc. These can be used alone or in a mixture thereof.

In another example embodiment of the present invention, the second lower electrode film 105 may have a double layer structure that includes the first metal oxide and the first metal. For example, the second lower electrode film 105 has a double layer structure of strontium ruthenium oxide on iridium or iridium oxide on iridium.

The second lower electrode film 105 may be formed by an E-beam evaporation process, a sputtering process, a CVD process, an ALD process or a PLD process. In an example embodiment of the present invention, the second lower electrode film 105 may be formed using iridium by the sputtering process. The second lower electrode film 105 may have a thickness of about 500 to about 1,500 Å measured from an upper face of the first lower electrode film 100.

In an example embodiment of the present invention, an adhesion layer may be provided between the insulation structure and the lower electrode 110 or between the substrate and the lower electrode 110. The adhesion layer may improve adhesion strength between the lower electrode 110 and the insulation structure or between the lower electrode 110 and the substrate. The adhesion layer may include a second metal and/or a second metal nitride. For example, the adhesion layer may include titanium (Ti), tantalum (Ta), aluminum (Al), tungsten (W), titanium nitride, tantalum nitride, aluminum nitride, tungsten nitride, etc. These can be used alone or in a mixture thereof. Additionally, the adhesion layer may be formed by an E-beam evaporation process, a sputtering process, a CVD process, an ALD process and/or a PLD process. For example, the adhesion layer may be formed using titanium by the sputtering process.

The first lower electrode film 100 may serve as a barrier layer that reduces or prevents diffusion of oxygen atoms included in the ferroelectric layer 115. The second lower electrode film 105 may improve crystallization of a ferroelectric material included in the ferroelectric layer 115. When the adhesion layer is not formed between the substrate and the lower electrode 110 or between the insulation structure and the lower electrode 110, the first lower electrode film 100 may enhance adhesion strength between the substrate and the second lower electrode film 105 or between the insulation structure and the second lower electrode film 105. In other words, the first lower electrode film 100 may simultaneously serve as a barrier layer and an adhesion layer.

The ferroelectric layer 115 is formed on the second lower electrode film 105.

In one example embodiment of the present invention, the ferroelectric layer 115 may include ferroelectric material such as BaTiO₃, PZT [(Pb, Zr)TiO₃], SBT (SrBi₂Ta₂O₉), BLT [(Bi, La)TiO₃], PLZT [Pb(La, Zr)TiO₃] and/or BST [(Bi, Sr)TiO₃], etc.

In another example embodiment of the present invention, the ferroelectric layer 115 may include ferroelectric material doped with a metal. For example, the ferroelectric layer 115 may include the ferroelectric material such as BaTiO₃, PZT, SBT, BLT, PLZT and/or BST, each of which is doped with calcium (Ca), lanthanum (La), manganese (Mg) and/or bismuth (Bi).

In still another example embodiment of the present invention, the ferroelectric layer 115 may include a metal oxide having a ferroelectric property. For example, the ferroelectric layer 115 may include titanium oxide (TiO₂), tantalum oxide (Ta₂O₅), aluminum oxide (Al₂O₃), zinc oxide (ZnO₂) and/or hafnium oxide (HfO₂), etc.

The ferroelectric layer 115 may be formed by a metal organic chemical vapor deposition (MOCVD) process, a sol-gel process, a liquid phase epitaxy (LPE) process or an ALD process. In an example embodiment of the present invention, the ferroelectric layer 115 may be formed using PZT by the MOCVD process. The ferroelectric layer 115 may have a thickness of about 200 to about 1,200 Å based on an upper face of the second lower electrode film 105.

The upper electrode 130 includes a first upper electrode film 120 and a second upper electrode film 125 on the ferroelectric layer 115.

The first upper electrode film 120 may include a second metal oxide. For example, the first upper electrode film 120 may include indium tin oxide (In₂Sn₂O₇; ISO), iridium oxide, strontium ruthenium oxide (SRO), strontium titanium oxide (SrTiO₃; STO), lanthanum nickel oxide (LnNiO₃; LNO) and/or calcium ruthenium oxide (CaRuO₃; CRO), etc. These can be used alone or in a mixture thereof.

In one example embodiment of the present invention, the second metal oxide in the first upper electrode film 120 may be substantially the same as the first metal oxide in the second lower electrode film 105.

In another example embodiment of the present invention, the first metal oxide in the second lower electrode film 105 may be different from the second metal oxide in the first upper electrode film 120.

The first upper electrode film 120 may have a thickness of about 10 to about 300 Å measured from an upper face of the ferroelectric layer 115. The first upper electrode film 120 may be formed by an E-beam evaporation process, a sputtering process, a CVD process, an ALD process and/or a PLD process. In an example embodiment of the present invention, the first upper electrode film 120 may be formed using strontium ruthenium oxide by the sputtering process.

The second upper electrode film 125 may include a second alloy. For example, the second upper electrode film 125 may include an alloy of iridium and ruthenium, an alloy of iridium and platinum, an alloy of iridium and palladium and/or an alloy of ruthenium and platinum, an alloy of ruthenium and palladium, an alloy of platinum and palladium, etc. These can be used alone or in a mixture thereof.

When the second upper electrode film 125 includes the alloy of iridium and ruthenium, the second upper electrode film 125 may include about 30 to about 50 percent by weight of iridium and about 50 to about 70 percent by weight of ruthenium. Accordingly, a content ratio between iridium and ruthenium in the second upper electrode film 125 may be in a range of about 1.0:1.0 to about 1.0:1.4. In an example embodiment of the present invention, the second upper electrode film 125 may include about 40 percent by weight of iridium and about 60 percent by weight of ruthenium. The second upper electrode film 125 may have a thickness of about 300 to about 1,000 Å based on an upper face of the first upper electrode film 120.

In one example embodiment of the present invention, the second alloy in the second upper electrode film 125 may be substantially the same as the first alloy in the second lower electrode film 105.

In another example embodiment of the present invention, the first alloy in the second lower electrode film 105 may be different from the second alloy in the second upper electrode film 125.

The second upper electrode film 125 may be formed by an E-beam evaporation process, a sputtering process, a CVD process, an ALD process and/or a PLD process. When the second upper electrode film 125 is formed by the sputtering process, a first target including iridium and a second target including ruthenium may be simultaneously used to form the second upper electrode film 125 including the alloy of iridium and ruthenium. Particularly, while sputtering iridium onto the first upper electrode film 120 from the first target, ruthenium may be sputtered onto the first upper electrode film 120 from the second target, thereby forming the second upper electrode film 125 including the alloy of iridium and ruthenium. In the sputtering process for forming the second upper electrode film 125, the first target and the second target may be positioned along different axes with respect to the substrate. In addition, the contents of iridium and ruthenium in the second upper electrode film 125 may be adjusted by controlling powers applied to the first and the second targets. According to another embodiment of the present invention, the second upper electrode film 125 may be formed using one target including an alloy of iridium and ruthenium by the sputtering process.

After the upper electrode 130 is formed on the ferroelectric layer 115, the upper electrode 130 having the first and the second upper electrode films 120 and 125 is thermally treated so as to reduce or prevent volatilization of a metal such as ruthenium, titanium or nickel in the first upper electrode film 120 and to simultaneously at least partially cure damage to the second upper electrode film 125 generated in the sputtering process. The upper electrode 130 may be thermally treated by a rapid thermal process (RTP). Additionally, the first and the second upper electrode films 120 and 125 may be thermally treated under an atmosphere including an oxygen gas, a nitrogen gas or a mixture gas of oxygen and nitrogen. For example, the upper electrode 130 may be thermally treated at a temperature of about 500 to about 700° C. for about 30 seconds to about 2 minutes.

FIG. 4 is a cross-sectional view illustrating another ferroelectric structure in accordance with an example embodiment of the present invention.

Referring to FIG. 4, a ferroelectric structure 190 includes an adhesion layer 150, a lower electrode 165 having a first lower electrode film 155 and a second lower electrode film 160, a ferroelectric layer 170, and an upper electrode 185 having a first upper electrode film 175 and a second upper electrode film 180.

The adhesion layer 150 may be directly formed on a substrate (not shown). Alternatively, an insulation and/or other structure may be formed between the substrate and the adhesion layer 150. A lower conductive structure including a contact region, a pad, a plug, a conductive wiring, a conductive pattern and/or a transistor may be formed on the substrate. Here, the adhesion layer 150 may make direct contact with the lower conductive structure. Alternatively, the adhesion layer 150 may be electrically connected to the lower conductive structure.

The adhesion layer 150 may be formed on the substrate or the insulation structure using a metal and/or a metal nitride by an E-beam evaporation process, a sputtering process, a CVD process, an ALD process and/or a PLD process. The adhesion layer 150 may enhance adhesion strength between the substrate and the first lower electrode film 155 or between the insulation structure and the first lower electrode film 155. Accordingly, the first lower electrode film 155 may not be lifted from the substrate or the insulation structure.

The first lower electrode film 155 is on the adhesion layer 150. The first lower electrode film 155 may be formed using a metal and/or a metal nitride by an E-beam evaporation process, a sputtering process, a CVD process, an ALD process and/or a PLD process. The first lower electrode film 155 may reduce or prevent diffusion of oxygen atoms in the ferroelectric layer 170.

The second lower electrode film 160 is on the first lower electrode film 155. The second lower electrode film 160 may be formed using a metal, an alloy and/or a metal nitride formed by an E-beam evaporation process, a sputtering process, a CVD process, an ALD process and/or a PLD process.

In one example embodiment of the present invention, the second lower electrode film 160 may have a single layer structure that includes iridium, ruthenium, platinum, palladium, iridium oxide, ruthenium oxide, strontium ruthenium oxide and/or iridium ruthenium oxide, etc.

In another example embodiment of the present invention, the second lower electrode film 160 may have a double layer structure that includes strontium ruthenium oxide on iridium and/or iridium oxide on iridium.

The ferroelectric layer 170 is on the second lower electrode film 160. The ferroelectric layer 170 may include a ferroelectric material, a ferroelectric material doped with a metal and/or a metal oxide having a ferroelectric property. The ferroelectric layer 170 may be formed by a MOCVD process, a sol-gel process, an LPE process and/or an ALD process.

The first upper electrode film 175 is on the ferroelectric layer 170. The first upper electrode film 175 may be formed using a metal oxide by an E-beam evaporation process, a sputtering process, a CVD process, an ALD process and/or a PLD process.

The second upper electrode film 180 is on the first upper electrode film 175. The second upper electrode film 180 may be formed using an alloy by an E-beam evaporation process, a sputtering process, a CVD process, an ALD process and/or a PLD process. For example, the second upper electrode film 180 may include an alloy of iridium and ruthenium that contains about 30 to about 50 percent by weight of iridium and about 50 to about 70 percent by weight of ruthenium.

In one example embodiment of the present invention, the second upper electrode film 180 may be formed simultaneously using an iridium target and a ruthenium target by the sputtering process. Contents of iridium and ruthenium in the second upper electrode film 180 may be adjusted by controlling power supplied to the iridium target and the ruthenium target.

In another example embodiment of the present invention, the second upper electrode film 180 may be formed using one alloy target of iridium and ruthenium by the sputtering process.

After the upper electrode 185 is formed on the ferroelectric layer 170, the upper electrode layer 185 having the first and the second upper electrode films 175 and 180 may be thermally treated. Therefore, volatilization of a metal, such as ruthenium, titanium or nickel, in the first upper electrode film 175 may be reduced or prevented and simultaneously damage to the second upper electrode film 180 may be reduced or cured.

Ferroelectric Capacitor and Manufacturing Method Thereof

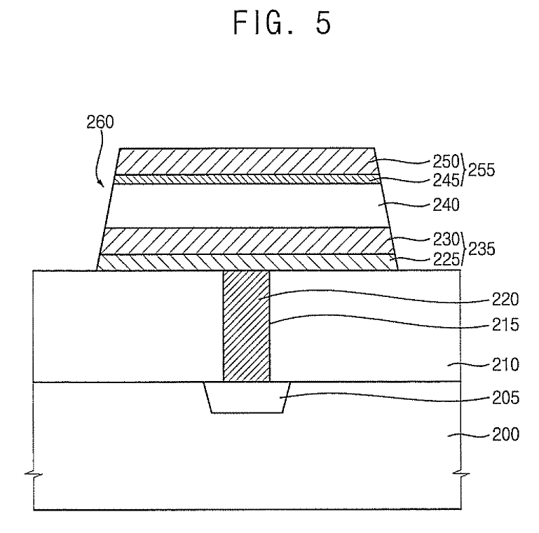

FIG. 5 is a cross-sectional view illustrating a ferroelectric capacitor in accordance with an example embodiment of the present invention.

Referring to FIG. 5, a ferroelectric capacitor 260 includes a substrate 200 having a lower structure 205, an insulation structure 210 on the substrate 200, a pad 220 contacting with the lower structure 205 through the insulation structure 210, a lower electrode 235 on the pad 220 and the insulation structure 210, a ferroelectric layer pattern 240 on the lower electrode 235, and an upper electrode 255 on the ferroelectric layer pattern 240.

The substrate 200 may include a silicon wafer, a single crystalline metal oxide substrate, an SOI substrate and/or any other substrate. The lower structure 205 may include a contact region, a pad, a conductive pattern, a conductive wiring, a gate structure and/or a transistor.

The insulation structure 210 is on the substrate 200 to cover the lower structure 205. The insulation structure 210 may include at least one insulation layer on the substrate 200. The insulation structure 210 may include an oxide, a nitride and/or an oxynitride, etc. For example, the insulation structure 210 includes borophosphosilicate glass (BPSG), phosphosilicate glass (PSG), undoped silicate glass (USG), spin on glass (SOG), flowable oxide (FOX), tetraethyl orthosilicate (TEOS), plasma enhanced-tetraethyl orthosilicate (PE-TEOS) and/or high density plasma-chemical vapor deposition (HDP-CVD) oxide, etc.

An opening 215 exposing the lower structure 205 is formed through the insulation structure 210. The pad 220 is on the lower structure 205 and can fill up the opening 215. The pad 220 may include a metal and/or a metal nitride. For example, the pad 220 includes tungsten, aluminum, titanium, tantalum, copper, tungsten nitride, aluminum nitride, titanium nitride and/or tantalum nitride, etc.

The lower electrode 235 includes a first lower electrode film pattern 225 and a second lower electrode film pattern 230.

The first lower electrode film pattern 225 is on the insulation structure 210 and the pad 220. The first lower electrode film pattern 225 may include a first metal nitride such as titanium nitride, aluminum nitride, titanium aluminum nitride, tungsten nitride, tantalum nitride, titanium silicon nitride and/or tantalum silicon nitride, etc. The first lower electrode film pattern 225 may have a thickness of about 50 to about 500 Å measured from an upper face of the insulation structure 210. The first lower electrode film pattern 225 is electrically connected to the lower structure 205 through the pad 220. The first lower electrode film pattern 225 may improve adhesion strength between the insulation structure 210 and the lower electrode 235. Additionally, the first lower electrode film pattern 225 may reduce or prevent oxygen atoms in the ferroelectric layer pattern 240 from diffusing toward the insulation structure 210 and/or the lower structure 205.

The second lower electrode film pattern 230 is on the first lower electrode film pattern 225. The second lower electrode film pattern 230 may have a thickness of about 500 to about 1,500 Å based on an upper face of the first lower electrode film pattern 225. The second lower electrode film pattern 230 may include a first metal, a first metal oxide and/or a first alloy. For example, the second lower electrode film pattern 230 includes iridium, platinum, ruthenium, palladium, iridium oxide, strontium ruthenium oxide, ruthenium oxide and/or an alloy of iridium and ruthenium. The second lower electrode film pattern 230 may have a double layer structure that includes the first metal oxide and the first metal.

The lower electrode 235 including the first and the second lower electrode film patterns 225 and 230 may have a sidewall inclined by a relatively high angle with respect to the substrate 200. For example, the sidewall of the lower electrode 235 may have an inclined angle of about 80 to about 90°.

The ferroelectric layer pattern 240 is on the second lower electrode film pattern 230. The ferroelectric layer pattern 240 may include a ferroelectric material such as BaTiO₃, PZT, SBT, BLT, PLZT and/or BST, etc. Alternatively, the ferroelectric layer pattern 240 may include a ferroelectric material doped with a metal such as calcium, lanthanum, manganese and/or bismuth, etc. Furthermore, the ferroelectric layer pattern 240 may include a ferroelectric metal oxide such as titanium oxide, tantalum oxide, aluminum oxide, zinc oxide and/or hafnium oxide, etc. The ferroelectric layer pattern 240 may have a thickness of about 200 to about 1,200 Å measured from an upper face of the second lower electrode film pattern 230.

The ferroelectric layer pattern 240 may have a size substantially smaller than that of the lower electrode 235. The ferroelectric layer pattern 240 also has a sidewall inclined by a relatively high angle with respect to the substrate 200. For example, the ferroelectric layer pattern 240 may have a sidewall inclined by an angle of about 80 to about 90°.

The upper electrode 255 includes a first upper electrode film pattern 245 and a second upper electrode film pattern 250.

The first upper electrode film pattern 245 is on the ferroelectric layer pattern 240. The first upper electrode film pattern 245 may include a second metal oxide. For example, the first upper electrode film pattern 245 includes indium tin oxide, iridium oxide, strontium ruthenium oxide, strontium titanium oxide, lanthanum nickel oxide and/or calcium ruthenium oxide, etc. The first upper electrode film pattern 245 may have a thickness of about 10 to about 300 Å based on an upper face of the ferroelectric layer pattern 240.

The second upper electrode film pattern 250 is on the first upper electrode film pattern 245. The second upper electrode film pattern 250 may include a second alloy. For example, the second upper electrode film pattern 250 includes an alloy of iridium and ruthenium, an alloy of iridium and platinum, an alloy of iridium palladium, an alloy of ruthenium and platinum, an alloy of ruthenium and palladium, and/or an alloy of platinum and palladium, etc. In an example embodiment of the present invention, the second upper electrode film pattern 250 may include the alloy of iridium and ruthenium that contains about 30 to about 50 percent by weight of iridium and about 50 to about 70 percent by weight of ruthenium.

The upper electrode 255 including the first and the second upper electrode film patterns 245 and 250 has a size substantially smaller than that of the ferroelectric layer pattern 240. The upper electrode 255 may also have a sidewall inclined by a high angle relative to the substrate 200. For example, the upper electrode 255 has the sidewall inclined by an angle of about 80 to about 90°. Therefore, the ferroelectric capacitor 260 including the lower electrode 235, the ferroelectric layer pattern 240 and the upper electrode 255 has a sidewall inclined by a high angle with respect to the substrate 200. For example, an entire sidewall of the ferroelectric capacitor 260 may have an inclined angle of about 80 to about 90°. When the ferroelectric capacitor 260 has the highly inclined sidewall, the ferroelectric capacitor 260 may have an enlarged effective area so that the ferroelectric capacitor 260 may have improved data sensing margin and enhanced ferroelectric characteristics, such as data retention or polarization retention.

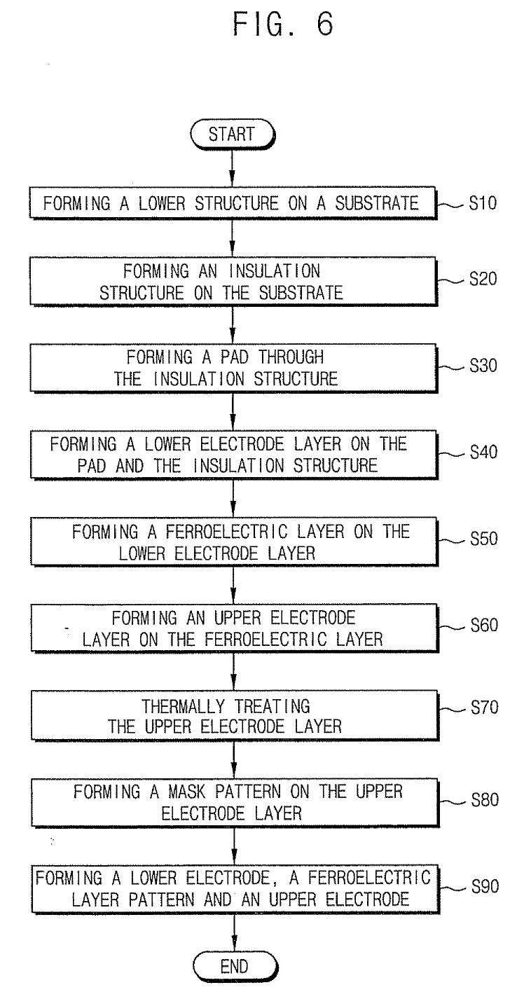

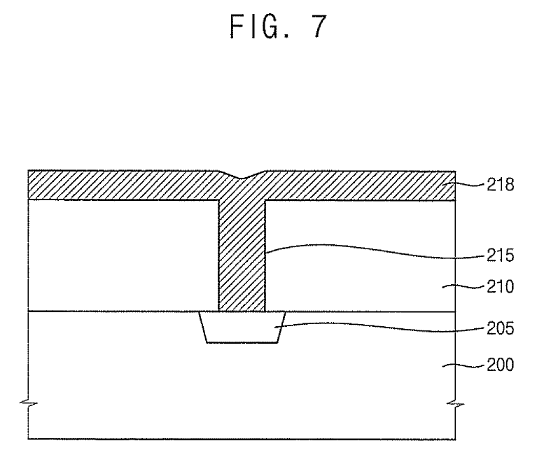

FIG. 6 is a flow chart illustrating methods of forming a ferroelectric capacitor in accordance with an example embodiment of the present invention. FIGS. 7 to 10 are cross-sectional views illustrating methods of forming the ferroelectric capacitor in FIG. 6.

Referring to FIGS. 6 and 7, a lower structure 205 is formed on a substrate 200 in step S10. The substrate 200 may include a silicon wafer, a single crystalline metal oxide substrate, an SOI substrate and/or any other substrate. The lower structure 205 may include a contact region, a conductive wiring, a conductive pattern, a pad, a plug, a gate structure and/or a transistor.

In step S20, an insulation structure 210 is formed on the substrate 200 to cover the lower structure 205. The insulation structure 210 may include at least one oxide layer, at least one nitride layer and/or at least one oxynitride layer. The insulation structure 210 may be formed by a CVD process, a plasma enhanced chemical vapor deposition (PECVD) process, an ALD process and/or a HDP-CVD process. For example, the insulation structure 210 is formed using PSG, BPSG, USG, SOG, FOX, TEOS, PE-TEOS, HDP-CVD oxide, silicon nitride and/or silicon oxynitride.

After a photoresist pattern (not shown) is formed on the insulation structure 210, the insulation structure 210 is partially etched using the photoresist pattern as an etching mask. Thus, an opening 215 partially exposing the lower structure 205 is formed through the insulation structure 210.

A conductive layer 218 is formed on the insulation structure 210 and may fill up the opening 215. The conductive structure 218 may be formed using a metal or a metal nitride by an E-beam evaporation process, a sputtering process, a CVD process, a PLD process and/or an ALD process. For example, the conductive layer 218 is formed using tungsten, aluminum, tantalum, copper, titanium, tungsten nitride, aluminum nitride, tantalum nitride and/or titanium nitride, etc.

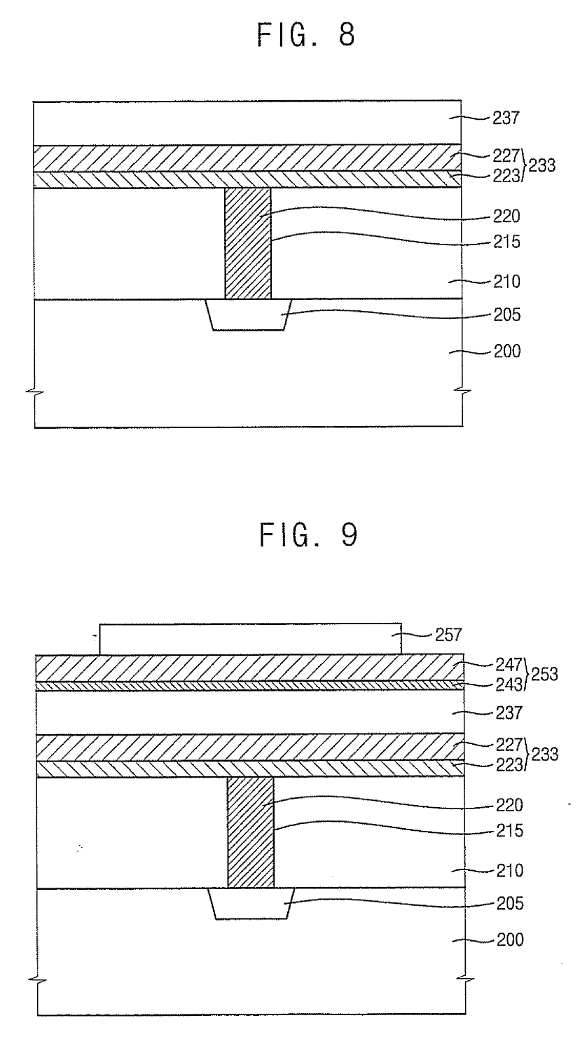

Referring to FIGS. 6 and 8, in step S30, the conductive layer 218 is partially removed by a chemical mechanical polishing (CMP) process and/or an etch back process until the insulation structure 210 is exposed. Thus, a pad 220 is formed in the opening 215. The pad 220 is formed on the exposed lower structure 205 and can fill up the opening 215.

In step S40, a lower electrode layer 233 is formed on the pad 220 and the insulation structure 210. The lower electrode layer 233 includes a first lower electrode film 223 and a second lower electrode film 227 sequentially formed on the pad 220 and the insulation structure 210.

The first lower electrode film 223 may be formed using a first metal nitride by an E-beam evaporation process, a sputtering process, a CVD process, an ALD process and/or a PLD process. For example, the first lower electrode film 223 may be formed using titanium nitride, aluminum nitride, titanium aluminum nitride, tantalum nitride, titanium silicon nitride and/or tantalum silicon nitride, etc.

The second lower electrode film 227 is formed on the first lower electrode film 223. The second lower electrode film 227 may be formed using a first metal, a first metal oxide and/or a first alloy. The second lower electrode film 227 may be formed by an E-beam evaporation process, a sputtering process, a CVD process, an ALD process and/or a PLD process. For example, the second lower electrode film 227 may be formed using iridium, platinum, ruthenium, iridium oxide, strontium ruthenium oxide, an alloy of iridium and ruthenium, strontium ruthenium oxide/iridium and/or iridium oxide/iridium, etc. In some embodiments, the substrate 200 having the first lower electrode film 223 is loaded into a reaction chamber, and then the second lower electrode film 227 is formed on the first lower electrode film 223 in the reaction chamber. The reaction chamber may have a relatively low temperature of about 20 to about 350° C. and a relatively low pressure of about 3 to about 10 mTorr. Additionally, the second lower electrode film 227 may be formed under an inert gas atmosphere by applying a power of about 300 to about 1,000 W. The inert gas atmosphere may include an argon (Ar) gas, a nitrogen (N₂) gas and/or a helium (He) gas, etc.

In step S50, a ferroelectric layer 237 is formed on the lower electrode layer 233. The ferroelectric layer 237 may be formed by a MOCVD process, an LPE process, a sol-gel process, a sputtering process, a PLD process and/or an ALD process. Additionally, the ferroelectric layer 237 may be formed using a ferroelectric material, a ferroelectric material doped with a metal, and/or a metal oxide having a ferroelectric property. For example, the ferroelectric layer 237 may be formed using the ferroelectric material such as BaTiO₃, PZT, PLZT, SBT, BLT and/or BST. Alternatively, the ferroelectric layer 237 may be formed using the ferroelectric material doped with calcium, lanthanum, manganese and/or bismuth. Further, the ferroelectric layer 237 may be formed using titanium oxide, tantalum oxide, aluminum oxide, zinc oxide, and/or hafnium oxide, etc.

In some embodiments, when the ferroelectric layer 237 is formed by the MOCVD process, a reaction chamber has a temperature of about 500 to about 600° C. and a pressure of about 1.0 to about 10 Torr after the substrate 200 having the lower electrode layer 233 is loaded into the reaction chamber. After a metal organic precursor is introduced onto the substrate 200, an oxidizing agent is provided onto the substrate 200 to thereby form the ferroelectric layer 237 including PZT on the lower electrode layer 233. The metal organic precursor may include a first compound containing lead (Pb), a second compound containing zirconium (Zr) and a third compound containing titanium (Ti). Alternatively, the metal organic precursor may directly include lead, zirconium and titanium. The oxidizing agent may include oxygen (O₂), ozone (O₃), nitrogen dioxide (NO₂) and/or nitrous oxide (N₂O), etc.

Referring to FIGS. 6 and 9, in step S60, an upper electrode layer 253 including a first upper electrode film 243 and a second upper electrode film 247 is formed on the ferroelectric layer 237.

The first upper electrode film 243 may be formed on the ferroelectric layer 237 using a second metal oxide by an E-beam evaporation process, a sputtering process, a CVD process, an ALD process and/or a PLD process. For example, the first upper electrode film 243 is formed using indium tin oxide, iridium oxide strontium ruthenium oxide, strontium titanium oxide, lanthanum nickel oxide and/or calcium ruthenium oxide, etc.

In the sputtering process for forming the first upper electrode film 243, a reaction chamber may have a temperature of about 300° C. to about 400° C. and a pressure of about 3 to about 10 mTorr after the substrate 200 including the ferroelectric layer 237 is loaded into the reaction chamber. Additionally, the first upper electrode film 243 may be formed under an inert gas atmosphere by applying a power of about 300 to about 1,000 W. The inert gas atmosphere may include an argon gas only.

The second upper electrode film 247 is formed on the first upper electrode film 243. The second upper electrode film 247 may be formed using a second alloy by an E-beam evaporation process, a sputtering process, a CVD process, an ALD process and/or a PLD process. For example, the second upper electrode film 247 may be formed using an alloy of iridium and ruthenium, an alloy of iridium and platinum, an alloy of iridium and palladium an alloy of ruthenium and platinum, an alloy of ruthenium and palladium and/or an alloy of platinum and palladium.

In some embodiments, a first target of iridium and a second target of ruthenium are simultaneously used to form the second upper electrode film 247 while applying a power of about 400 to about 600 W to the first and the second targets after the substrate 200 having the first upper electrode film 243 is loaded into a reaction chamber. The reaction chamber may be at room temperature and a pressure of about 3 to about 10 mTorr. The first target and the second target are disposed along different axes relative to the substrate 200. The first target may be separated from the second target by less than about 10 mm. The second upper electrode film 247 may be formed under an inert gas atmosphere containing an argon gas. For example, the argon gas is introduced into the reaction chamber by a flow rate of about 30 sccm. As a result, the second upper electrode film 247 may include about 30 to about 50 percent by weight of iridium and about 50 to about 70 percent by weight of ruthenium. Contents of iridium and ruthenium in the second upper electrode film 247 may be adjusted by controlling the power applied to the first and the second targets.

Alternatively, the second upper electrode film 247 may be formed by the sputtering process using one target including iridium and ruthenium. The target of iridium and ruthenium may include about 30 to about 50 percent by weight of iridium and about 50 to about 70 percent by weight of ruthenium.

In step S70, the upper electrode layer 253 is thermally treated so as to reduce or prevent volatilization of metal included in the first upper electrode film 243 and in order to at least partially cure damage to the second upper electrode film 247 generated in the sputtering process. The upper electrode layer 253 may be thermally treated by a RTP under an atmosphere including an oxygen gas, a nitrogen gas or a mixture gas of oxygen and nitrogen. For example, the first and the second upper electrode films 243 and 247 may be thermally treated at a temperature of about 500 to about 700° C. for about 30 seconds to about 2 minutes.

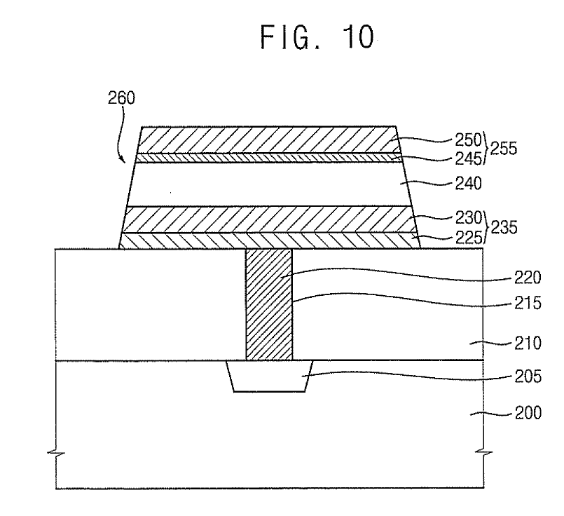

In step S80, a hard mask pattern 257 is formed on the second upper electrode film 247 for forming a ferroelectric capacitor 260 (see FIG. 10). The hard mask pattern 257 may be formed using an oxide, a nitride, an oxynitride and/or a metal oxide. For example, the hard mask pattern 257 may be formed using silicon oxide, silicon nitride, silicon oxynitride and/or strontium ruthenium oxide. In addition, the hard mask pattern 257 may be formed by a CVD process, a sputtering process, an E-beam evaporation process, an ALD process and/or a PLD process.

Referring to FlGS. 6 and 10, the upper electrode layer 253, the ferroelectric layer 237 and the lower electrode layer 233 are etched using the hard mask pattern 257 as an etching mask, thereby forming a lower electrode 235, a ferroelectric layer pattern 240 and an upper electrode 255 over the substrate 200 in step S90. Therefore, the ferroelectric capacitor 260 having the lower electrode 235, the ferroelectric layer pattern 240 and the upper electrode 255 is formed on the pad 220 and the insulation structure 210. The lower electrode 235 includes a first lower electrode film pattern 225 and a second lower electrode film pattern 230. The upper electrode 255 has a first upper electrode film pattern 245 and a second upper electrode film pattern 250.

In an example embodiment of the present invention, the ferroelectric capacitor 260 having the ferroelectric layer pattern 240 and the upper electrode 255 may be thermally treated so as to crystallize materials in the first upper electrode film pattern 245 and the ferroelectric layer pattern 240. The first upper electrode film pattern 245 and the ferroelectric layer pattern 240 may be thermally treated by an RTP under an atmosphere including an oxygen gas, a nitrogen gas or a mixture gas of oxygen and nitrogen. For example, the ferroelectric layer pattern 240 and the first upper electrode film pattern 245 are thermally treated at a temperature of about 500 to about 650° C. for about 30 seconds to about 3 minutes.

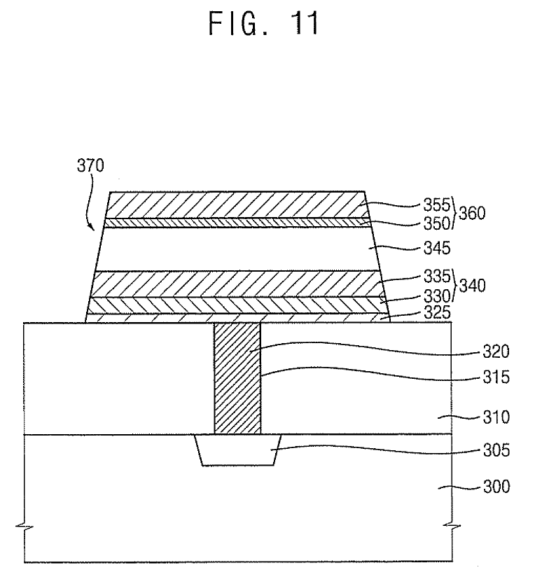

FIG. 11 is a cross-sectional view illustrating a ferroelectric capacitor in accordance with an example embodiment of the present invention.

Referring to FIG. 11, a ferroelectric capacitor 370 includes a substrate 300, a lower structure 305 on the substrate 300, an insulation structure 310 on the substrate 300, a pad 320 contacting with the lower structure 305 through the insulation structure 310, an adhesion layer pattern 325 on the pad 320 and the insulation structure 310, a lower electrode 340 on the adhesion layer pattern 325, a ferroelectric layer pattern 345 on the lower electrode 340, and an upper electrode 360 on the ferroelectric layer pattern 345.

The lower electrode 340 includes a first lower electrode film pattern 330 and a second lower electrode film pattern 335 sequentially formed on the adhesion layer pattern 325. The upper electrode 360 includes a first upper electrode film pattern 350 and a second upper electrode film pattern 355 successively formed on the ferroelectric layer pattern 345.

The lower electrode 305 may include a contact region, a pad, a conductive pattern, a conductive wiring, a gate structure and/or a transistor. The insulation structure 310 covers the lower structure 305. The insulation structure 310 may include at least one insulation layer. For example, the insulation structure 310 includes an oxide such as BPSG, PSG, USG, SOG, FOX, TEOS, PE-TEOS and/or HDP-CVD oxide, a nitride such as silicon nitride, and/or an oxynitride such as silicon oxynitride.

An opening 315 exposing the lower structure 305 is formed through the insulation structure 310. The pad 320 is formed on the exposed lower structure 305 and can fill up the opening 315. The pad 320 may include a metal or a metal nitride. For example, the pad 320 includes tungsten, aluminum, titanium, tantalum, copper, tungsten nitride, aluminum nitride, titanium nitride and/or tantalum nitride, etc.

The adhesion layer pattern 325 is formed on the insulation structure 310 and the pad 320. The adhesion layer pattern 325 may include a metal and/or a metal nitride. For example, the adhesion layer pattern 325 includes titanium, tantalum, aluminum, tungsten, titanium nitride, tantalum nitride, aluminum nitride and/or tungsten nitride, etc. The adhesion layer pattern 325 has a sidewall inclined by a relatively high angle of about 80 to about 90° with respect to the substrate 300. The adhesion layer pattern 325 may enhance adhesion strength between the insulation structure 310 and the first lower electrode film pattern 330.

The first lower electrode film pattern 330 is formed on the adhesion layer pattern 325. The first lower electrode film pattern 330 may include a first metal nitride. For example, the first lower electrode film pattern 330 includes titanium nitride, aluminum nitride, titanium aluminum nitride, tungsten nitride, tantalum nitride, titanium silicon nitride and/or tantalum silicon nitride, etc. The first lower electrode film pattern 330 may have a thickness of about 50 to about 500 Å measured from an upper face of the adhesion layer pattern 325. The first lower electrode film pattern 330 is electrically connected to the lower structure 305 through the pad 320 and the adhesion layer pattern 325. The first lower electrode film pattern 330 may serve as a barrier layer that reduces or prevents oxygen atoms in the ferroelectric layer pattern 345 from diffusing toward the insulation structure 310 and/or the lower structure 305. The first lower electrode film pattern 330 has a size substantially smaller than that of the adhesion layer pattern 325.

The second lower electrode film pattern 335 is on the first lower electrode film pattern 330. The second lower electrode film pattern 335 may have a thickness of about 500 to about 1,500 Å based on an upper face of the first lower electrode film pattern 330. The second lower electrode film pattern 335 may include a first metal, a first metal oxide and/or a first alloy. For example, the second lower electrode film pattern 335 may include iridium, platinum, ruthenium, palladium, iridium oxide, strontium ruthenium oxide, ruthenium oxide and/or an alloy of iridium and ruthenium. In one example embodiment of the present invention, the second lower electrode film pattern 335 may have a single layer structure including the first metal, the first metal oxide or the first alloy. In another example embodiment of the present invention, the second lower electrode film pattern 335 may have a double layer structure that includes the first metal oxide and the first metal. The second lower electrode film pattern 335 has a size substantially smaller than the first lower electrode film pattern 330. Therefore, the lower electrode 340 including the first and the second lower electrode film patterns 330 and 335 may have a sidewall inclined by a high angle of about 80 to about 90° relative to the substrate 300.

The ferroelectric layer pattern 345 is on the second lower electrode film pattern 335. The ferroelectric layer pattern 345 may include a ferroelectric material such as BaTiO₃, PZT, SBT, BLT, PLZT and/or BST, etc. Alternatively, the ferroelectric layer pattern 345 may include the ferroelectric material doped with a metal such as calcium, lanthanum, manganese and/or bismuth, etc. Furthermore, the ferroelectric layer pattern 345 may include a metal oxide having a ferroelectric property such as titanium oxide, tantalum oxide, aluminum oxide, zinc oxide and/or hafnium oxide, etc. The ferroelectric layer pattern 345 may have a thickness of about 200 to about 1,200 Å measured from an upper face of the second lower electrode film pattern 335. The ferroelectric layer pattern 345 has a size substantially smaller than that of the lower electrode 340. The ferroelectric layer pattern 345 also may have a sidewall inclined by a high angle of about 80 to about 90° with respect to the substrate 300.

The first upper electrode film pattern 350 is on the ferroelectric layer pattern 345. The first upper electrode film pattern 350 may include a second metal oxide, such as indium tin oxide, iridium oxide, strontium ruthenium oxide, strontium titanium oxide, lanthanum nickel oxide and/or calcium ruthenium oxide, etc. The first upper electrode film pattern 350 may have a thickness of about 10 to about 300 Å based on an upper face of the ferroelectric layer pattern 345. The first upper electrode film pattern 350 has a size substantially smaller than that of the ferroelectric layer pattern 345.

The second upper electrode film pattern 355 is formed on the first upper electrode film pattern 350. The second upper electrode film pattern 355 may include a second alloy, such as an alloy of iridium and ruthenium, an alloy of iridium and platinum, an alloy of iridium and palladium, an alloy of ruthenium and platinum, an alloy of ruthenium and palladium and/or an alloy of platinum and palladium, etc. In an example embodiment of the present invention, the second upper electrode film pattern 355 may include the alloy of iridium and ruthenium that contains about 30 to about 50 percent by weight of iridium and about 50 to about 70 percent by weight of ruthenium. The second upper electrode film pattern 355 has a size substantially smaller than that of the first upper electrode film pattern 350.

The upper electrode 360 including the first and the second upper electrode film patterns 350 and 355 has an entire size substantially smaller than that of the ferroelectric layer pattern 345. As described above, the upper electrode 360 also may have a sidewall inclined by a high angle of about 80 to about 90° relative to the substrate 300. Therefore, the ferroelectric capacitor 370 including the adhesion layer pattern 325, the lower electrode 340, the ferroelectric layer pattern 345 and the upper electrode 360 may have a sidewall inclined by a high angle of about 80 to about 90° relative to the substrate 300.

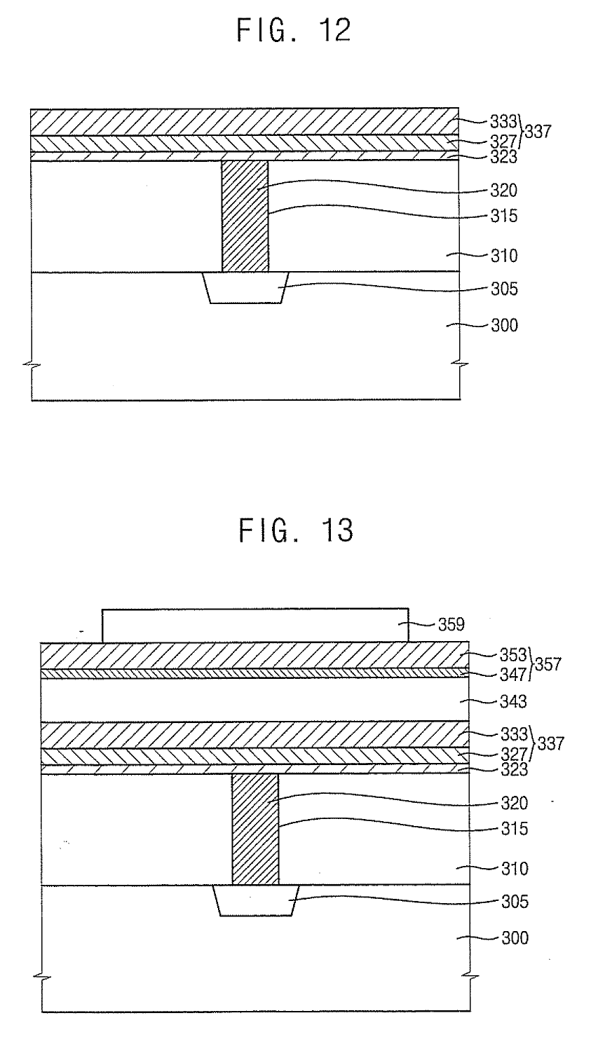

FIGS. 12 to 14 are cross-sectional views illustrating methods of forming the ferroelectric capacitor in FIG. 11.

Referring to FIG. 12, after a lower structure 305 having a contact region is formed on a substrate 300, an insulation structure 310 is formed on the substrate 300 to cover the lower structure 305. The insulation structure 310 may include at least one oxide layer, at least one nitride layer and/or at least one oxynitride layer. The insulation structure 310 may be formed by a CVD process, a plasma enhanced chemical vapor deposition (PECVD) process, an ALD process and/or a HDP-CVD process.

After a first photoresist pattern (not shown) is formed on the insulation structure 310, the insulation structure 310 is partially etched using the first photoresist pattern as an etching mask, thereby forming an opening 315 through the insulation structure 310. The opening 315 partially exposes the lower structure 305.

A conductive layer is formed on the insulation structure 310 and can fill up the opening 315 using a metal or a metal nitride by an E-beam evaporation process, a sputtering process, a CVD process, a PLD process and/or an ALD process. The conductive layer may be formed using tungsten, aluminum, tantalum, copper, titanium, tungsten nitride, aluminum nitride, tantalum nitride and/or titanium nitride, etc.

The conductive layer is partially removed by a CMP process and/or an etch back process until the insulation structure 310 is exposed so that a pad 320 is formed in the opening 315. The pad 320 in the opening 315 makes contact with the exposed lower structure 305. Then, the first photoresist pattern is removed by an ashing process and/or a stripping process.

An adhesion layer 323 is formed on the insulation structure 310 and the pad 320. The adhesion layer 323 may be formed using a metal and/or a metal nitride by an E-beam evaporation process, a CVD process, a sputtering process, an ALD process and/or a PLD process. For example, the adhesion layer 323 may be formed using titanium, tantalum, aluminum, tungsten, titanium nitride, tantalum nitride, aluminum nitride and/or tungsten nitride, etc.

A lower electrode layer 337 is formed on the adhesion layer 323. The lower electrode layer 337 includes a first lower electrode film 327 and a second lower electrode film 333 sequentially formed on the adhesion layer 323.

The first lower electrode film 327 may be formed using a first metal nitride by an E-beam evaporation process, a sputtering process, a CVD process, an ALD process and/or a PLD process. For example, the first lower electrode film 327 may be formed using titanium nitride, aluminum nitride, titanium aluminum nitride, tantalum nitride, titanium silicon nitride and/or tantalum silicon nitride, etc.

The second lower electrode film 333 is formed on the first lower electrode film 327. The second lower electrode film 333 may be formed using a first metal, a first metal oxide and/or a first alloy. Additionally, the second lower electrode film 333 may be formed by an E-beam evaporation process, a sputtering process, a CVD process, an ALD process and/or a PLD process. For example, the second lower electrode film 333 may be formed using iridium, platinum, ruthenium, iridium oxide, strontium ruthenium oxide, an alloy of iridium and ruthenium, strontium ruthenium oxide/iridium and/or iridium oxide/iridium, etc.

Referring to FIG. 13, a ferroelectric layer 343 is formed on the lower electrode layer 337. The ferroelectric layer 343 may be formed by a MOCVD process, an LPE process, a sol-gel process, a sputtering process, a PLD process and/or an ALD process. In addition, the ferroelectric layer 343 may be formed using a ferroelectric material, a ferroelectric material doped with a metal, or a metal oxide having a ferroelectric property. For example, the ferroelectric layer 343 is formed using the ferroelectric material such as BaTiO₃, PZT, PLZT, SBT, BLT or BST. Alternatively, the ferroelectric layer 343 may be formed using the ferroelectric material doped with calcium, lanthanum, manganese and/or bismuth. Furthermore, the ferroelectric layer 343 may be formed using titanium oxide, tantalum oxide, aluminum oxide, zinc oxide and/or hafnium oxide, etc.

An upper electrode layer 357 including a first upper electrode film 347 and a second upper electrode film 353 is formed on the ferroelectric layer 343.

The first upper electrode film 347 may be formed on the ferroelectric layer 343 using a second metal oxide by an E-beam evaporation process, a sputtering process, a CVD process, an ALD process and/or a PLD process. For example, the first upper electrode film 347 may be formed using indium tin oxide, iridium oxide strontium ruthenium oxide, strontium titanium oxide, lanthanum nickel oxide and/or calcium ruthenium oxide, etc.

The second upper electrode film 353 is formed on the first upper electrode film 347. The second upper electrode film 353 may be formed using a second alloy by an E-beam evaporation process, a sputtering process, a CVD process, an ALD process and/or a PLD process. For example, the second upper electrode film 353 may be formed using an alloy of iridium and ruthenium, an alloy of iridium and platinum, an alloy of iridium and palladium, an alloy of ruthenium and platinum, an alloy of ruthenium and palladium and/or an alloy of platinum and palladium.

The upper electrode layer 357 is thermally treated so as to reduce or avoid volatilization of metal included in the first upper electrode film 347 and in order to at least partially cure damage to the second upper electrode film 353. The upper electrode layer 357 may be thermally treated at a temperature of about 500 to about 700° C. for about 30 seconds to about 2 minutes by a RTP under an atmosphere including an oxygen gas, a nitrogen gas or a mixture gas of oxygen and nitrogen.

After a hard mask layer is formed on the second upper electrode film 353, a second photoresist pattern (not shown) is formed on the hard mask layer. The hard mask layer may be formed using an oxide, a nitride, an oxynitride and/or a metal oxide. For example, the hard mask layer may be formed using silicon oxide, silicon nitride, silicon oxynitride and/or strontium ruthenium oxide. The hard mask layer may be formed by a CVD process, a sputtering process, an E-beam evaporation process, an ALD process and/or a PLD process.

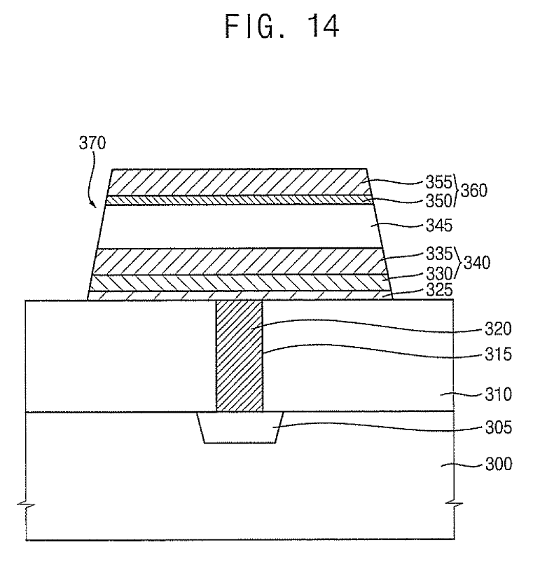

The hard mask layer is partially etched using the second photoresist pattern as an etching mask to form a hard mask pattern 359 for forming a ferroelectric capacitor 370 (see FIG. 14) on the second upper electrode film 353.

Referring to FIG. 14, the upper electrode layer 357, the ferroelectric layer 343, the lower electrode layer 337 and the adhesion layer 323 are sequentially etched using the hard mask pattern 359 as an etching mask, thereby forming an adhesion layer pattern 325, a lower electrode 340, a ferroelectric layer pattern 345 and an upper electrode 360 over the substrate 300. As a result, the ferroelectric capacitor 370 having the adhesion layer pattern 325, the lower electrode 340, the ferroelectric layer pattern 345 and the upper electrode 360 is formed on the pad 320 and the insulation structure 310. The lower electrode 340 includes a first lower electrode film pattern 330 and a second lower electrode film pattern 335. The upper electrode 360 has a first upper electrode film pattern 350 and a second upper electrode film pattern 355. The ferroelectric capacitor 370 having the ferroelectric layer pattern 345 and the upper electrode 360 may be thermally treated so that materials in the first upper electrode film pattern 350 and the ferroelectric layer pattern 345 may be crystallized.

Measurement of Characteristics of Ferroelectric Capacitors

Hereinafter, the electrical and ferroelectric characteristics of ferroelectric capacitors in accordance with various Examples and Comparative Examples of embodiments of the present invention will be described.

### EXAMPLE 1

A lower electrode layer having a first lower electrode film and a second lower electrode film was formed on a substrate by a sputtering process. The first lower electrode film was formed using titanium aluminum nitride and the second lower electrode film was formed using iridium.

A ferroelectric layer was formed on the second lower electrode film at a temperature of about 575° C. using PZT by a MOCVD process.

A first upper electrode film was formed on the ferroelectric layer at a temperature of about 350° C. using strontium ruthenium oxide by a sputtering process. The first upper electrode film was formed under an argon atmosphere. The first upper electrode film had a thickness of about 50 Å.

A second upper electrode film was formed on the first upper electrode film by simultaneously sputtering iridium and ruthenium onto the first upper electrode film under an argon atmosphere. The second upper electrode film included about 40 percent by weight of iridium and about 60 percent by weight of ruthenium. The second upper electrode film had a thickness of about 1,000 Å.

The substrate having the first and the second upper electrode films was thermally treated at a temperature of about 600° C. for about 60 seconds by a rapid thermal process. The first and the second upper electrode films were thermally treated under an oxygen atmosphere.

The second upper electrode film, the first upper electrode film, the ferroelectric layer and the lower electrode layer were etched to form a ferroelectric capacitor having a lower electrode, a ferroelectric layer pattern and an upper electrode on the substrate.

### EXAMPLE 2

A lower electrode layer having a first lower electrode film and a second lower electrode film was formed on a substrate by a sputtering process. The first lower electrode film was formed using titanium aluminum nitride and the second lower electrode film was formed using iridium. A ferroelectric layer was formed on the second lower electrode film at a temperature of about 575° C. using PZT by a MOCVD process.

A first upper electrode film was formed on the ferroelectric layer at a temperature of about 350° C. using strontium ruthenium oxide by a sputtering process. The first upper electrode film was formed under an argon atmosphere. The first upper electrode film had a thickness of about 50 Å.

A second upper electrode film was formed on the first upper electrode film by simultaneously sputtering iridium and ruthenium onto the first upper electrode film under an argon atmosphere. The second upper electrode film included about 50 percent by weight of iridium and about 50 percent by weight of ruthenium. The second upper electrode film had a thickness of about 1,000 Å.

The substrate having the first and the second upper electrode films was thermally treated at a temperature of about 600° C. for about 60 seconds by a rapid thermal process. The first and the second upper electrode films were thermally treated under an oxygen atmosphere.

The second upper electrode film, the first upper electrode film, the ferroelectric layer and the lower electrode layer were etched to form a ferroelectric capacitor having a lower electrode, a ferroelectric layer pattern and an upper electrode on the substrate.

### COMPARATIVE EXAMPLE 1

A lower electrode layer having a first lower electrode film and a second lower electrode film was formed on a substrate. The first lower electrode film was formed using titanium aluminum nitride by a sputtering process and the second lower electrode film was formed using iridium by a sputtering process. A ferroelectric layer was formed on the second lower electrode film at a temperature of about 575° C. using PZT by a MOCVD process.

A first upper electrode film was formed on the ferroelectric layer at a temperature of about 350° C. using strontium ruthenium oxide by a sputtering process. The first upper electrode film was formed under an argon atmosphere. The first upper electrode film had a thickness of about 50 Å.

A second upper electrode film was formed on the first upper electrode film by sputtering iridium onto the first upper electrode film at a room temperature. The second upper electrode film was formed under an argon atmosphere. The second upper electrode film including iridium had a thickness of about 600 Å.

The substrate having the first and the second upper electrode films was thermally treated at a temperature of about 600° C. for about 60 seconds by a rapid thermal process. The first and the second upper electrode films were thermally treated under an oxygen atmosphere.

The second upper electrode film, the first upper electrode film, the ferroelectric layer and the lower electrode layer were etched to form a ferroelectric capacitor having a lower electrode, a ferroelectric layer pattern and an upper electrode on the substrate.

### COMPARATIVE EXAMPLE 2

A lower electrode layer having a first lower electrode film and a second lower electrode film was formed on a substrate. The first lower electrode film was formed using titanium aluminum nitride by a sputtering process and the second lower electrode film was formed using platinum by a sputtering process. A ferroelectric layer was formed on the second lower electrode film at a temperature of about 575° C. using PZT by a MOCVD process.

A first upper electrode film was formed on the ferroelectric layer at a temperature of about 350° C. using strontium ruthenium oxide by a sputtering process. The first upper electrode film was formed under an argon atmosphere. The first upper electrode film had a thickness of about 50 Å.

A second upper electrode film was formed on the first upper electrode film by sputtering iridium onto the first upper electrode film at a room temperature. The second upper electrode film was formed under an argon atmosphere. The second upper electrode film including iridium had a thickness of about 600 Å.

The substrate having the first and the second upper electrode films was thermally treated at a temperature of about 600° C. for about 60 seconds by a rapid thermal process. The first and the second upper electrode films were thermally treated under an oxygen atmosphere.

The second upper electrode film, the first upper electrode film, the ferroelectric layer and the lower electrode layer were etched to form a ferroelectric capacitor having a lower electrode, a ferroelectric layer pattern and an upper electrode on the substrate.

FIG. 15 is a graph illustrating a variation of a stress generated between the first and the second upper electrode films in the ferroelectric capacitor according to Example 1.

Referring to FIG. 15, the stress generated between the first and the second upper electrode films of the ferroelectric capacitor according to Example 1 is about 2.69×10⁹ dyne/cm² which is about one-tenth of that generated in the conventional ferroelectric capacitor in FIG. 2. Thus, according to Example 1, the stress generated in the upper electrode of the ferroelectric capacitor may be greatly reduced in comparison with the conventional ferroelectric capacitor. In the conventional ferroelectric capacitor, the stress generated in the upper electrode may be converted from the compressive stress into the tensile stress to thereby deteriorate electrical and ferroelectric characteristics of the conventional ferroelectric capacitor as shown in FIG. 2. However, in the ferroelectric capacitor of Example 1, the stress generated in the upper electrode may not be converted from a compressive stress into a tensile stress as shown in FIG. 15. Thus, an interfacial layer (e.g., a dead layer) may not be formed between the ferroelectric layer pattern and the upper electrode so that the ferroelectric capacitor may have improved ferroelectric characteristics.

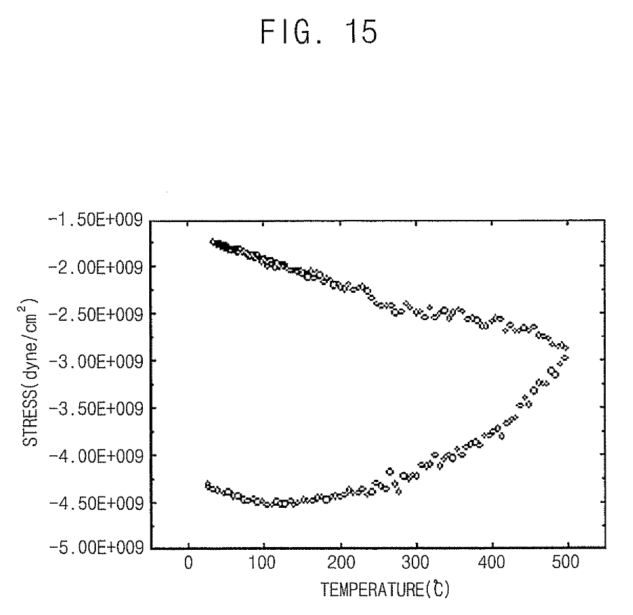

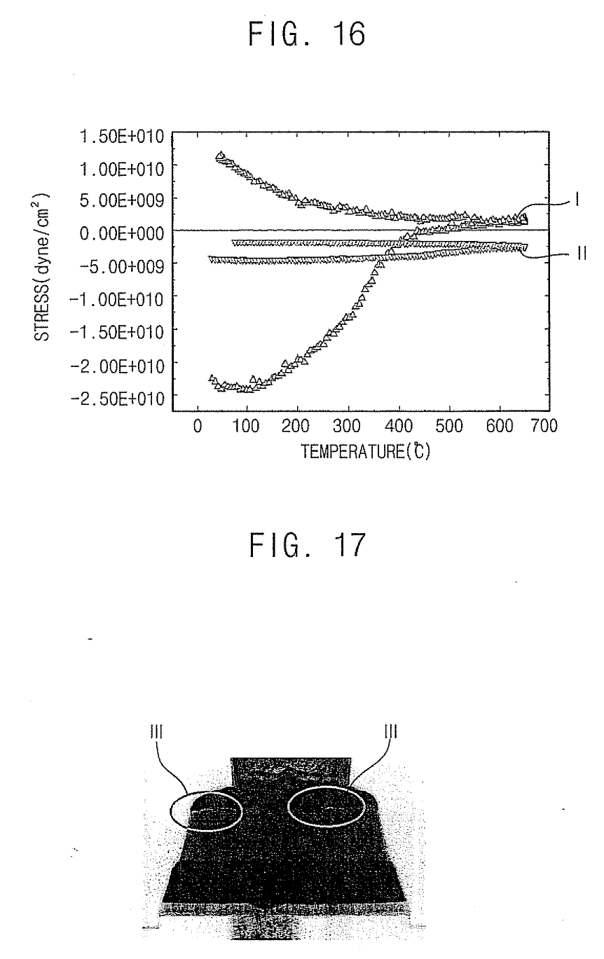

FIG. 16 is a graph illustrating variations of stresses generated in the upper electrodes of the ferroelectric capacitors relative to a temperature according to Example 1 and Comparative Example 1. FIG. 17 is an electron microscopic picture showing a cross-section of the ferroelectric capacitor according to Comparative Example 1. In FIG. 16, “I” indicates a variation of a stress generated between the first and the second upper electrode films of the ferroelectric capacitor according to Comparative Example 1 and “II” represents a variation of a stress generated between the first and the second upper electrode films of the ferroelectric capacitor according to Example 1.

Referring to FIG. 16, the ferroelectric capacitor of Example 1 has the stress variation (I) substantially lower than the stress variation (II) of the ferroelectric capacitor of Comparative Example 1. In the ferroelectric capacitor of Comparative Example 1, as shown in FIG. 17, defects (III), such as lifting of the upper electrode may occur between the ferroelectric layer pattern and the upper electrode that has the first upper electrode film pattern of strontium ruthenium oxide and the second upper electrode film pattern of iridium.

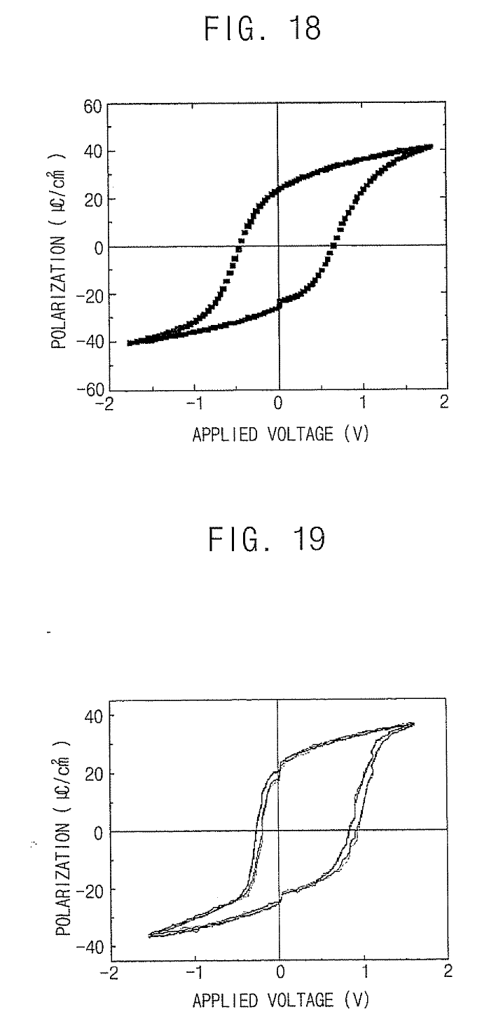

FIG. 18 is a graph showing a polarization-voltage (P-V) hysteresis of the ferroelectric capacitor according to Comparative Example 1. FIG. 19 is a graph showing P-V hysteresis of the ferroelectric capacitor according to Comparative Example 2.

As shown in FIG. 18, in the ferroelectric capacitor of Comparative Example 1, +Vc is about 0.65V and −Vc is about −0.45V. Additionally, the ferroelectric capacitor of Comparative Example 1 has +2Pr value of about 41 μC/cm² and −2Pr value of about −40 μC/cm². Although the ferroelectric capacitor of Comparative Example 1 has relatively good polarization characteristics, the ferroelectric capacitor of Comparative Example 1 has deteriorated ferroelectric characteristics because +Vc and −Vc are asymmetric each other due to the stress generated in the upper electrode.

Referring to FIG. 19, the ferroelectric capacitor of Comparative Example 2 has +Vc of about 0.87V and −Vc of about −0.23V. In addition, the ferroelectric capacitor of Comparative Example 2 has +2Pr value of about 39 μC/cm² and −2Pr value of about −38 μC/cm². The ferroelectric capacitor of Comparative Example 2 has somewhat low polarization characteristics and deteriorated ferroelectric characteristics because +Vc and −Vc are asymmetric due to the stress generated in the upper electrode. Particularly, the ferroelectric capacitor of Comparative Example 2 has the P-V hysteresis in which a positive shift may become serious as time passes because of an excessive stress generated therein. Hence, a failure of the ferroelectric capacitor of Comparative Example 2 may occur in a process for testing a reliability of the ferroelectric capacitor.

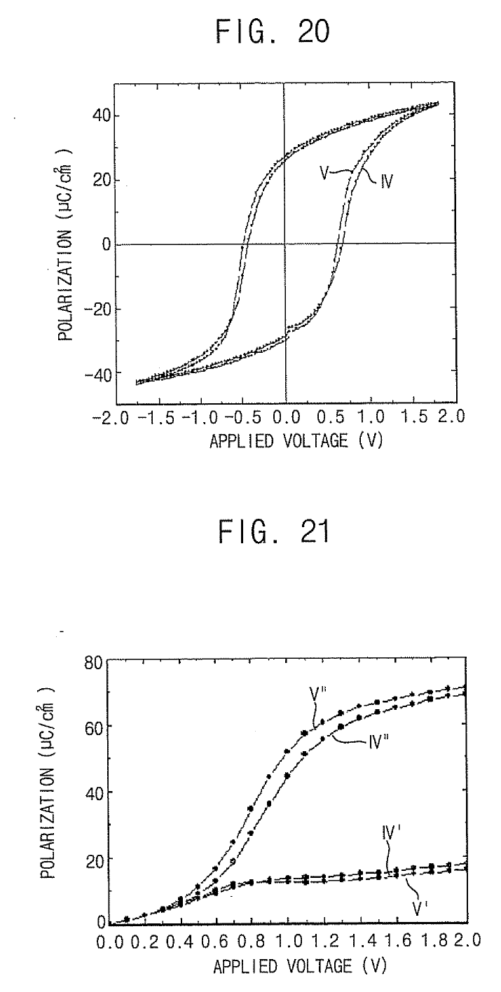

FIG. 20 is a graph showing P-V hysteresis of the ferroelectric capacitors according to Example 1 and Comparative Example 1. In FIG. 20, “IV” represents the P-V hysteresis of the ferroelectric capacitor according to Comparative Example 1 and “V” indicates the P-V hysteresis of the ferroelectric capacitor according to Example 1.

As shown in FIG. 20, the ferroelectric capacitor of Comparative Example 1 has 2Pr value of about 42.3 μC/cm² when an applied voltage is about 1.22V. However, the ferroelectric capacitor of Example 1 has 2Pr value of about 46.38 μC/cm² when an applied voltage is about 1.14V. Thus, the ferroelectric capacitor of Example 1 may have ferroelectric characteristics superior to those of the ferroelectric capacitor according to Comparative Example 1.

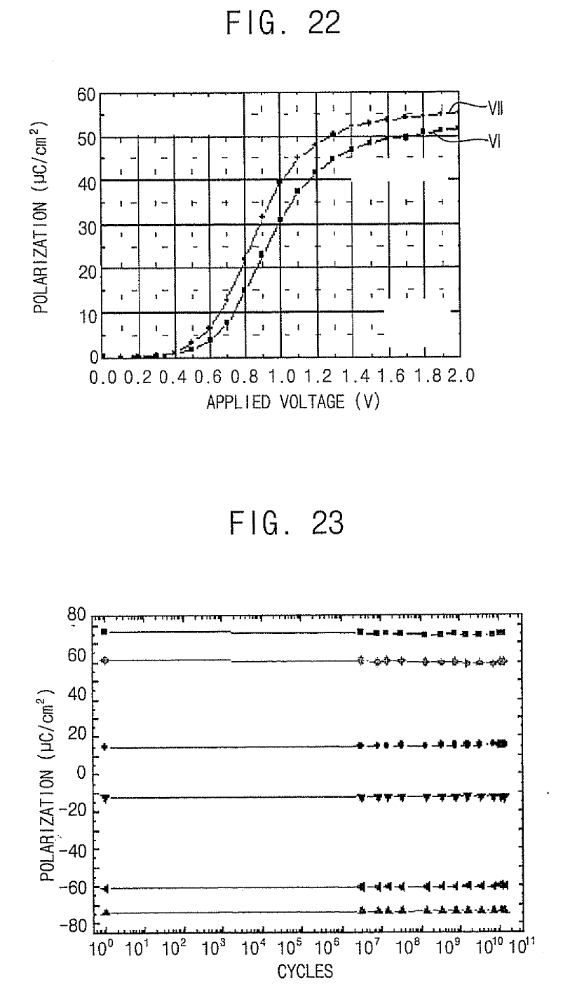

FIG. 21 is a graph showing maximum and minimum polarization values of the ferroelectric capacitors according to Example 1 and Comparative Example 1. In FIG. 21, “IV′” denotes the minimum polarization value of the ferroelectric capacitor according to Comparative Example 1 and “V′” represents the minimum polarization value of the ferroelectric capacitor according to Example 1. In addition, “IV″” represents the maximum polarization value of the ferroelectric capacitor according to Comparative Example 1 and “V″” represents the maximum polarization value of the ferroelectric capacitor according to Example 1. FIG. 22 is a graph showing 2Pr values of the ferroelectric capacitors according to Example 1 and Comparative Example 1. In FIG. 22, “VI″” means the 2Pr value of the ferroelectric capacitor according to Comparative Example 1 and “VII″” denotes the 2Pr value of the ferroelectric capacitor according to Example 1.

Referring to FIGS. 21 and 22, the ferroelectric capacitor of Comparative Example 1 has the maximum polarization value (IV″) of about 69 μC/cm² and the minimum polarization value (IV′) of about 17 μC/cm² when an applied voltage is about 2.0V. Thus, the ferroelectric capacitor of Comparative Example 1 has the 2Pr value of about 52 μC/cm². On the other hand, when an applied voltage is about 2.0V, the ferroelectric capacitor of Example 1 has the maximum polarization value (V″) of about 71 μC/cm² and the minimum polarization value (V′) of about 15 μC/cm². Hence, the ferroelectric capacitor of Example 1 has the 2Pr value of about 56 μC/cm².

As shown in FIGS. 20 to 22, the ferroelectric capacitor of Example 1 including the second upper electrode film of iridium and ruthenium has ferroelectric characteristics better than those of the ferroelectric capacitor of Comparative Example 1 including the second upper electrode film of iridium.

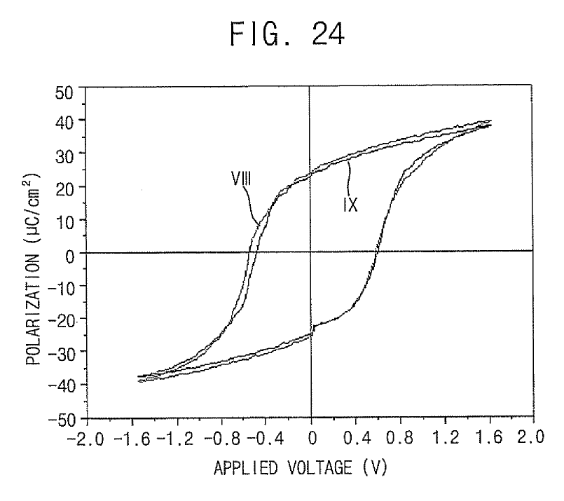

FIG. 23 is a graph showing a polarization variation of the ferroelectric capacitor according to Example 1. In FIG. 23, the polarization variation of the ferroelectric capacitor is obtained relative to the number of programming cycles for the ferroelectric capacitor at a temperature of about 85° C. by applying a voltage of about 1.6V. Further, the polarization variation of the ferroelectric capacitor is obtained after programming is repeatedly performed on the ferroelectric capacitor by the number of about 1.17×10¹⁰ times. In FIG. 23, “▪” represents the maximum polarization value of the ferroelectric capacitor, “●” indicates the minimum polarization value and “▴” means 2Pr value of the ferroelectric capacitor. FIG. 24 is a graph showing a variation of a P-V hysteresis of the ferroelectric capacitor according to Example 1. In FIG. 24, the variation of the P-V hysteresis is obtained relative to the number of programming cycles for the ferroelectric capacitor.

Referring to FIGS. 23 and 24, the ferroelectric capacitor of Example 1 has initial −2Pr value of about −48.293 μC/cm² to about −46.694 μC/cm². After programming is repeatedly performed on the ferroelectric capacitor by the number of about 1.17×10¹⁰ times, the ferroelectric capacitor of Example 1 has −2Pr value of about 96.7 percent of the initial −2Pr value.

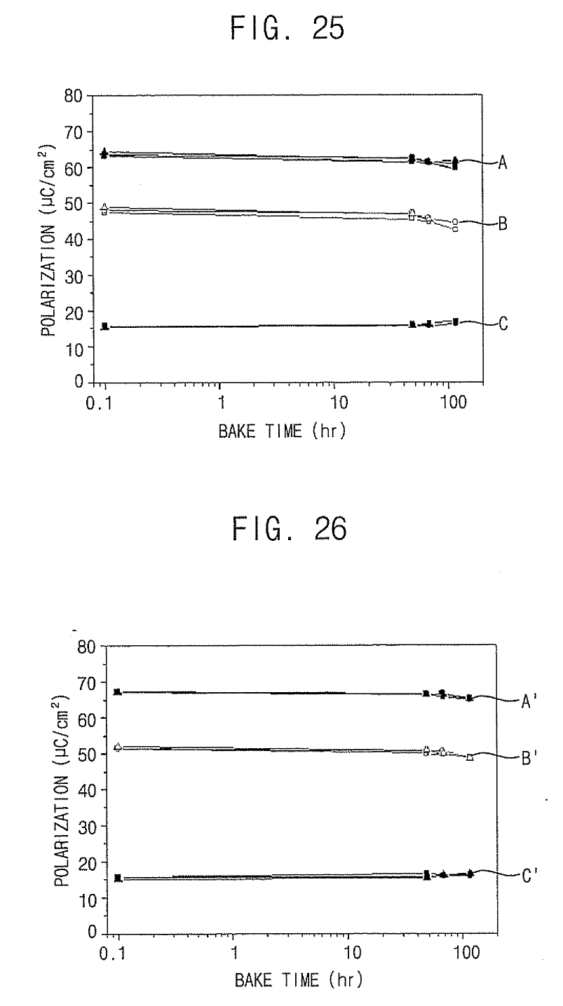

FIG. 25 is a graph showing a polarization variation of the ferroelectric capacitor according to Comparative Example 1, and FIG. 26 is a graph showing a polarization variation of the ferroelectric capacitor according to Example 1. In FIGS. 25 and 26, each of the polarization variations of the ferroelectric capacitors is obtained relative to time. In FIGS. 25 and 26, “A” and “A′” indicate first polarization values of the ferroelectric capacitors of Comparative Example 1 and Example 1 after about 48 hours at a temperature of about 150° C., respectively. Additionally, “B” and “B′” respectively denote second polarization values of the ferroelectric capacitors of Comparative Example 1 and Example 1 after about 67.5 hours at a temperature of about 150° C. Furthermore, “C” and “C′” represent third polarization values of the ferroelectric capacitors of Comparative Example 1 and Example 1 after about 115.5 hours at a temperature of about 150° C., respectively.

Referring to FIG. 25, the first polarization value (A) of the ferroelectric capacitor according to Comparative Example 1 is about 96.5 percent of an initial polarization value. The second polarization value (B) and the third polarization (C) of the ferroelectric capacitor according to Comparative Example 1 are about 94.2 percent of an initial polarization value and about 90.5 percent of the initial polarization value. However, as shown in FIG. 26, the first polarization value (A′), the second polarization value (B′) and the third polarization value (C′) of the ferroelectric capacitor according to Example 1 are about 97.5 percent of an initial polarization value, about 96.7 percent of the initial polarization value and about 94.4 percent of the initial polarization value.

As shown in FIGS. 25 and 26, the ferroelectric capacitor of Example 1 has a polarization retention characteristic superior to that of the ferroelectric capacitor of Comparative Example 1. Accordingly, the ferroelectric capacitor of Example 1 may have better ferroelectric characteristics than those of the ferroelectric capacitor of Comparative Example 1.

Semiconductor Device and Manufacturing Method Thereof

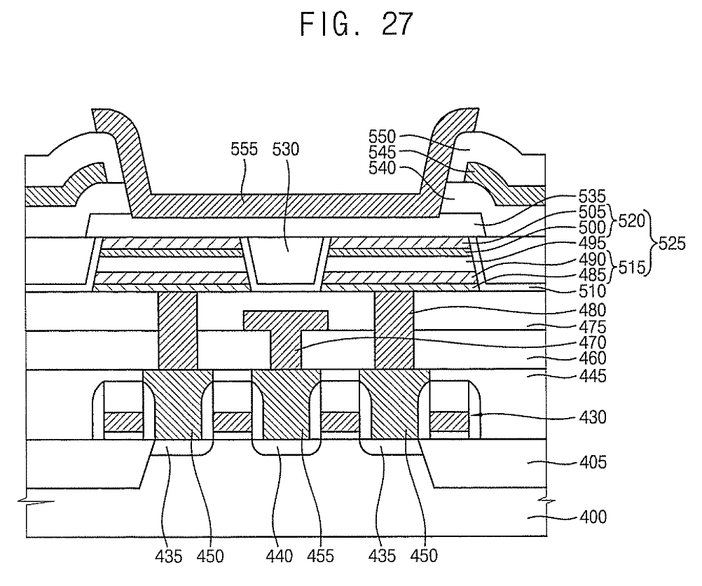

FIG. 27 is a cross-sectional view illustrating a semiconductor device in accordance with an example embodiment of the present invention.

Referring to FIG. 27, the semiconductor device such as an FRAM device includes a transistor formed on a substrate 400 and a ferroelectric capacitor 525 formed over the transistor.

The transistor includes a gate structure 430, a first contact region 435 and a second contact region 440. A first insulating interlayer 445 is on the substrate 400 to cover the transistors.

A first pad 450 is positioned on the first contact region 435 and a second pad 455 is on the second contact region 440. The first and the second pads 450 and 455 are buried in the first insulating interlayer 445. A second insulating interlayer 460 is on the first pad 450, the second pad 455 and the first insulating interlayer 445.

A lower wiring 470 is on the second insulating interlayer 460. The lower wiring 470 makes contact with the second pad 455 through the second insulating interlayer 460.

A third insulating interlayer 475 is on the second insulating interlayer 460 to cover the lower wiring 470. A third pad 480 extends through the third insulating interlayer 475 and the second insulating interlayer 460. The third pad 480 makes contact with the first pad 450.

The ferroelectric capacitor 525 is positioned on the third pad 480 and the third insulating interlayer 475. The ferroelectric capacitor 525 includes a lower electrode 515, a ferroelectric layer pattern 495 and an upper electrode 520. The lower electrode 515 has a first lower electrode film pattern 485 and a second lower electrode film pattern 490. The upper electrode 520 includes a first upper electrode film pattern 500 and a second upper electrode film pattern 505.

A barrier layer 510 is on the third insulating interlayer 475 and a sidewall of the ferroelectric capacitor 525. A fourth insulating interlayer 530 is on the barrier layer 510.

A local plate line 535 is on the fourth insulating interlayer 530 and the upper electrode 520 of the ferroelectric capacitor 525. A main plate line 555 is positioned on the local plate line 535.

A fifth insulating interlayer 540 partially covers the local plate line 535 and an upper wiring 545 is on the fifth insulating interlayer 540. A sixth insulating interlayer 550 is on the fifth insulating interlayer 540 to cover the upper wiring 545.

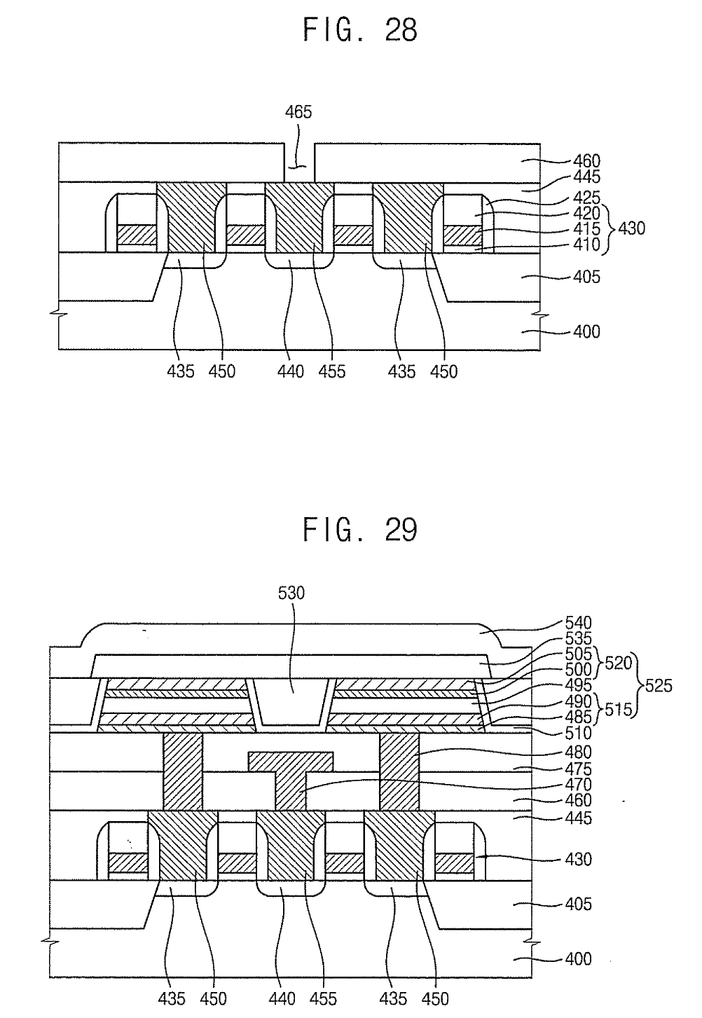

FIGS. 28 to 30 are cross-sectional views illustrating methods of manufacturing a semiconductor device in accordance with an example embodiment of the present invention.

Referring to FIG. 28, an isolation layer 405 is formed on a substrate 400 by an isolation process such as a shallow trench isolation (STI) process or a local oxidation of silicon (LOCOS) process so as to define an active region and a field region. The substrate 400 may include a silicon wafer, an SOI substrate and/or any other substrate.

After a thin gate oxide layer is formed on the active region of the substrate 400 by a thermal oxidation process or a CVD process, a gate conductive layer and a gate mask layer are sequentially formed on the thin gate oxide layer. The gate conductive layer may be formed using polysilicon doped with impurities and the gate mask layer may be formed using a nitride such as silicon nitride.

After a first photoresist pattern (not shown) is formed on the gate mask layer, the gate mask layer, the gate conductive layer and the gate oxide layer are etched using the first photoresist pattern as an etching mask. Thus, gate structures 430 are formed on the substrate 400. Each of the gate structures 430 includes a gate oxide layer pattern 410, a gate conductive layer pattern 415 and a gate mask 420.

After a first insulation layer is formed on the substrate 400 using a nitride such as silicon nitride to cover the gate structures 430, the first insulation layer is anisotropically etched to form gate spacers 425 on sidewalls of the gate structures 430, respectively.

Impurities are implanted into portions of the substrate 400 exposed by the gate structures 430 using the gate structures 430 and the gate spacers 425 as ion implantation masks. Thus, a first contact region 435 and a second contact region 440 are formed at the exposed portions of the substrate 400. The first and the second contact regions 435 and 440 may correspond to source/drain regions, respectively. The first and the second contact regions 435 and 440 may be divided into a capacitor contact region and a lower wiring contact region. A ferroelectric capacitor 525 (see FIG. 29) is electrically connected to the capacitor contact region whereas a lower wiring 470 is electrically connected to the lower wiring contact region. As a result, transistors including the gate structures 430 and the contact regions 435 and 440 are formed on the substrate 400.

Referring now to FIG. 28, a first insulating interlayer 445 is formed on the substrate 400 using an oxide to cover the gate structures 430. For example, the first insulating interlayer 445 is formed using BPSG, PSG, SOG, PE-TEOS, USG and/or HDP-CVD oxide by a CVD process, PECVD process, an HDP-CVD process and/or an ALD process.

An upper portion of the first insulating interlayer 445 is partially removed by a CMP process and/or an etch back process, to thereby planarize the first insulating interlayer 445.

After a second photoresist pattern (not shown) is formed on the first insulating interlayer 445, portions of the first insulating interlayer 445 are anisotropically etched using the second photoresist pattern as an etching mask, thereby forming first contact holes that expose the first and the second contact regions 435 and 440, respectively. Here, some first contact holes expose the first contact regions 435 and another first contact hole exposes the second contact region 440.

After removing the second photoresist pattern by an ashing process and/or a stripping process, a first conductive layer is formed on the first insulating interlayer 445 and can fill up the first contact holes. The first conductive layer may be formed using polysilicon highly doped with impurities and/or a metal.

The first conductive layer is partially removed by a CMP process and/or an etch back process until the first insulating interlayer 445 is exposed. Thus, a first pad 450 and a second pad 455 are formed in the first contact holes. Since the first contact holes are formed through a self-alignment process, the first and the second pads 450 and 455 may correspond to self-aligned contact (SAC) pads, respectively. The first pad 450 makes contact with the first contact region 435 whereas the second pad 455 makes contact with the second contact region 440. Namely, the first pad 450 is positioned on the capacitor contact region and the second pad 455 is formed on the lower wiring contact region.

A second insulating interlayer 460 is formed on the first insulating interlayer 445 having the first pad 450 and the second pad 455. The second insulating interlayer 460 electrically insulates the first pad 450 from the lower wiring 470. The second insulating interlayer 460 may be formed using an oxide such as BPSG, PSG, SOG, PE-TEOS, USG and/or HDP-CVD oxide, etc. Additionally, the second insulating interlayer 460 may be formed by a CVD process, a PECVD process, an HDP-CVD process and/or an ALD process.

An upper portion of the second insulating interlayer 460 is removed by a CMP process and/or an etch back process so that the second insulating interlayer 460 is planarized.

After a third photoresist pattern (not shown) is formed on the second insulating interlayer 460, the second insulating interlayer 460 is partially etched using the third photoresist pattern as an etching mask. Hence, a second contact hole 465 is formed through the second insulating interlayer 460. The second contact hole 465 exposes the second pad 455 buried in the first insulating interlayer 445.

Referring to FIG. 29, after the third photoresist pattern is removed by an ashing process and/or a stripping process, a second conductive layer is formed on the second insulating interlayer 460 and can fill up the second contact hole 465. The second conductive layer may be formed using doped polysilicon or a metal.

After a fourth photoresist pattern (not shown) is formed on the second conductive layer, the second conductive layer is etched using the fourth photoresist pattern as an etching mask, thereby forming the lower wiring 470 filling up the second contact hole 465 on the second insulating interlayer 460.

A third insulating interlayer 475 is formed on the second insulating interlayer 460 to cover the lower wiring 470. The third insulating interlayer 475 may be formed using an oxide such as BPSG, PSG, SOG, PE-TEOS, USG and/or HDP-CVD oxide by a CVD process, a PECVD process, an HDP-CVD process and/or an ALD process. The third insulating interlayer 475 is planarized by a CMP process and/or an etch back process.

After a fifth photoresist pattern (not shown) is formed on the third insulating interlayer 475, the third insulating interlayer 475 and the second insulating interlayer 460 are partially etched using the fifth photoresist pattern as an etching mask. Thus, third contact holes exposing the first pads 450 are formed through the third insulating interlayer 475 and the second insulating interlayer 460. The third contact holes may correspond to capacitor contact holes. In an example embodiment of the present invention, a cleaning process may be performed to remove a native oxide film or particles from the first pads 450 after the third contact holes are formed.

Referring now to FIG. 29, after a third conductive layer is formed on the third insulating interlayer 475 that can fill up the third contact holes, the third conductive layer is partially removed by a CMP process and/or an etch back process until the third insulating interlayer 475 is exposed. Therefore, third pads 480 are formed in the third contact holes, respectively. Each of the third pads 480 may be formed using doped polysilicon or a metal. The third pad 480 electrically connects the first pad 450 to a lower electrode 515. That is, the lower electrode 515 is electrically contacted to the first contact region 450 through the third pad 480 and the first pad 450.

A first lower electrode film and a second lower electrode film are sequentially formed on the third pads 480 and the third insulating interlayer 475. The first lower electrode film may be formed using a first metal nitride by an E-beam evaporation process, a CVD process, a sputtering process and/or an ALD process. The second lower electrode film may be formed using a first metal, a first metal oxide and/or a first alloy by an E-beam evaporation process, a sputtering process, a CVD process, a PLD process and/or an ALD process.

In an example embodiment of the present invention, an adhesion layer may be formed on the third pad 480 and the third insulating interlayer 475 before formation of the first lower electrode film.

A ferroelectric layer is formed on the second lower electrode film. The ferroelectric layer may be formed using a ferroelectric material, a ferroelectric material doped with a metal or a ferroelectric metal oxide by an MOCVD process, an LPE process, a sol-gel process and/or an ALD process.

A first upper electrode film and a second upper electrode film are sequentially formed on the ferroelectric layer. The first upper electrode film may be formed using a second metal oxide by an E-beam evaporation process, a sputtering process, a CVD process, a PLD process and/or an ALD process, etc. The second upper electrode film may be formed using a second alloy by an E-beam evaporation process, a sputtering process, a CVD process, an ALD process and/or a PLD process.

After forming the second upper electrode film, the first and the second upper electrode films are thermally treated by an RTP under an atmosphere including an oxygen gas, a nitrogen gas or a mixture gas of oxygen and nitrogen.

Referring to FIG. 29, after a hard mask (not shown) is formed on the second upper electrode film, the second upper electrode film, the first upper electrode film, the ferroelectric layer, the second lower electrode film and the first lower electrode film are sequentially etched using the hard mask. Therefore, the ferroelectric capacitor 525 including the lower electrode 515, a ferroelectric layer pattern 495 and an upper electrode 520 is formed over the substrate 400. The lower electrode 515 includes a first lower electrode film pattern 485 and a second lower electrode film pattern 490 successively formed on the third pads 480 and the third insulating interlayer 475. The upper electrode 520 includes a first upper electrode film pattern 500 and a second upper electrode film pattern 505 sequentially formed on the ferroelectric layer pattern 495. The ferroelectric capacitor 525 may have a sidewall substantially inclined by a high angle of about 80 to about 90° relative to the substrate 400.

A barrier layer 510 is formed on the third insulating interlayer 475 to cover the ferroelectric capacitor 525. The barrier layer 510 may be formed using a metal oxide or a metal nitride by an E-beam evaporation process, a CVD process, a sputtering process, a PLD process and/or an ALD process. The barrier layer 510 reduces or prevents hydrogen atoms from diffusing into the ferroelectric layer pattern 495 so as to allow improved electrical and ferroelectric characteristics of the ferroelectric layer pattern 495.

A fourth insulating interlayer 530 is formed on the barrier layer 510. The fourth insulating interlayer 530 may be formed using an oxide such as BPSG, PSG, SOG, PE-TEOS, USG and/or HDP-CVD oxide by a CVD process, a PECVD process, an HDP-CVD process and/or an ALD process.

The fourth insulating interlayer 530 and the barrier layer 510 are partially removed by a CMP process and/or an etch back process until the upper electrode 520 is exposed.

A fourth conductive layer is formed on the exposed upper electrode 520 and the fourth insulating interlayer 530 by an E-beam evaporation process, a CVD process, a sputtering process, a PLD process and/or an ALD process. The fourth conductive layer may be formed using a metal, a metal oxide and/or a metal nitride.

After a sixth photoresist pattern (not shown) is formed on the fourth conductive layer, the fourth conductive layer is etched using the sixth photoresist pattern as an etching mask. Thus, a local plate line 535 that makes contact with the upper electrode 520 is formed. The local plate line 535 may commonly contact with adjacent upper electrodes 520 of adjacent ferroelectric capacitors 525.

A fifth insulating interlayer 540 is formed on the local plate line 535 and the fourth insulating interlayer 530. The fifth insulating interlayer 540 may be formed using an oxide such as BPSG, PSG, SOG, PE-TEOS, USG and/or HDP-CVD oxide by a CVD process, a PECVD process, an HDP-CVD process and/or an ALD process.

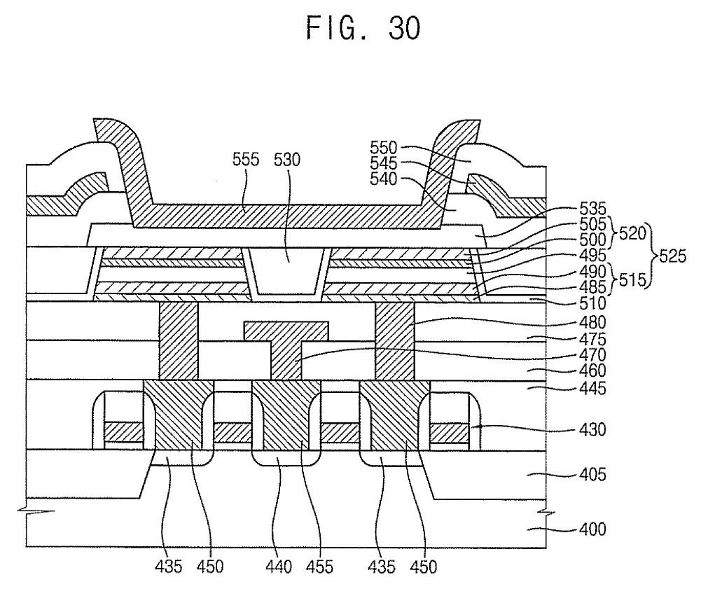

Referring to FIG. 30, a fifth conductive layer is formed on the fifth insulating interlayer 540. The fifth conductive layer may be formed using a metal or a metal nitride by an E-beam evaporation process, a sputtering process, an ALD process, a PLD process and/or a CVD process.

After a seventh photoresist pattern (not shown) is formed on the fifth conductive layer, the fifth conductive layer is partially etched using the seventh photoresist pattern as an etching mask, thereby forming an upper wiring 545 on the fifth insulating interlayer 540.

A sixth insulating interlayer 550 is formed on the upper wiring 545 and the fifth insulating interlayer 540. The sixth insulating interlayer 550 may be formed using an oxide such as BPSG, PSG, SOG, PE-TEOS, USG and/or HDP-CVD oxide by a CVD process, a PECVD process, an HDP-CVD process and/or an ALD process.

After an eighth photoresist pattern (not shown) is formed on the sixth insulating interlayer 550, the sixth insulating interlayer 550 is partially etched using the eighth photoresist pattern as an etching mask, thereby exposing the local plate line 535.

A sixth conductive layer is formed on the exposed local plate line 535 and on the eighth insulating interlayer 550. The sixth conductive layer may be formed using a metal or a metal nitride by an E-beam evaporation process, a sputtering process, a CVD process, an ALD process and/or a PLD process.

After a ninth photoresist pattern (not shown) is formed on the sixth conductive layer, the sixth conductive layer is partially etched using the ninth photoresist pattern as an etching mask, to thereby form a main plate line 555 that makes contact with the local plate line 535. As a result, the semiconductor device including the ferroelectric capacitor 525 is formed on the substrate 400.

According to some embodiments of the present invention, a first upper electrode film and a second upper electrode film are thermally treated after the first upper electrode film is formed using metal oxide and the second upper electrode film is formed using an alloy. Thus, a ferroelectric structure including the first and the second upper electrode films may have enhanced electrical and ferroelectric characteristics, such as improved polarization retention, data retention and/or fatigue resistance. As a result, a ferroelectric capacitor including the ferroelectric structure may also have improved electrical and ferroelectric characteristics.

Additionally, in some embodiments, the ferroelectric capacitor may have a sidewall inclined by a high angle of about 80 to about 90° because etching by-product such as ruthenium oxide (RuO₄) may be generated in an etching process for the second upper electrode film when the second upper electrode film includes the alloy of iridium and ruthenium. Therefore, the ferroelectric capacitor may have increased effective area so that the ferroelectric capacitor may have improved data sensing margin.

Furthermore, a semiconductor device including the ferroelectric capacitor may also have enhanced electrical and ferroelectric characteristics when the ferroelectric capacitor is employed in the semiconductor device.

The foregoing is illustrative of the present invention and is not to be construed as limiting thereof. Although a few example embodiments of this invention have been described, those skilled in the art will readily appreciate that many modifications are possible in the example embodiments without materially departing from the novel teachings and advantages of the present invention. Accordingly, all such modifications are intended to be included within the scope of the present invention as defined in the claims. Therefore, it is to be understood that the foregoing is illustrative of the present invention and is not to be construed as limited to the specific embodiments disclosed, and that modifications to the disclosed embodiments, as well as other embodiments, are intended to be included within the scope of the appended claims. The present invention is defined by the following claims, with equivalents of the claims to be included therein.

What is claimed is:

1. A ferroelectric structure comprising:
a lower electrode comprising a first lower electrode film and a second lower electrode film thereon, wherein the first lower electrode film includes a first metal nitride and the second lower electrode film includes a first metal, a first metal oxide and/or a first alloy;
a ferroelectric layer on the lower electrode; and
an upper electrode on the ferroelectric layer, wherein the upper electrode comprises a first upper electrode film including a second metal oxide and a second upper electrode film including a second alloy thereon.

2. The ferroelectric structure of claim 1, wherein the first lower electrode film comprises titanium nitride, aluminum nitride, titanium aluminum nitride, tantalum nitride, tungsten nitride, titanium silicon nitride and/or tantalum silicon nitride.

3. The ferroelectric structure of claim 1, wherein the second lower electrode film comprises iridium, platinum, ruthenium, palladium, iridium oxide, ruthenium oxide, strontium ruthenium oxide and/or an alloy of iridium and ruthenium.

4. The ferroelectric structure of claim 1, wherein the second lower electrode film has a double layer structure that includes the first metal and the first metal oxide.

5. The ferroelectric structure of claim 1, wherein the first metal oxide and the first alloy are substantially the same as the second metal oxide and the second alloy, respectively.

6. The ferroelectric structure of claim 1, wherein the ferroelectric layer comprises BaTiO₃, PZT, SBT, BLT, PLZT and/or BST.

7. The ferroelectric structure of claim 1, wherein the first upper electrode film comprises indium tin oxide, iridium oxide, strontium ruthenium oxide, strontium titanium oxide, lanthanum nickel oxide and/or calcium ruthenium oxide.

8. The ferroelectric structure of claim 1, wherein the second upper electrode film comprises an alloy of iridium and ruthenium, an alloy of iridium and platinum, an alloy of iridium and palladium, an alloy of ruthenium and platinum, an alloy of ruthenium and palladium and/or an alloy of platinum and palladium.

9. The ferroelectric structure of claim 1, wherein the second upper electrode film comprises about 30 to about 50 percent by weight of iridium and about 50 to about 70 percent by weight of ruthenium.

10. The ferroelectric structure of claim 1, wherein the second upper electrode film comprises iridium and ruthenium by a weight ratio of about 1.0:1.0 to about 1.0:1.4.

11. The ferroelectric structure of claim 1, further comprising an adhesion layer beneath the first lower electrode film wherein the adhesion layer comprises a second metal and/or a second metal nitride.

12. The ferroelectric structure of claim 11, wherein the adhesion layer comprises titanium, tantalum, aluminum, tungsten, titanium nitride, tantalum nitride, aluminum nitride and/or tungsten nitride.

13. The ferroelectric structure of claim 1 further comprising:
a substrate; and
a lower structure on the substrate;
wherein the lower electrode is electrically connected to the lower structure to provide a ferroelectric capacitor.

14. The ferroelectric structure of claim 13, wherein the second lower electrode film has a double layer structure that includes the first metal and the first metal oxide.

15. The ferroelectric structure of claim 13, wherein the first upper electrode film comprises indium tin oxide, iridium oxide, strontium ruthenium oxide, strontium titanium oxide, lanthanum nickel oxide and/or calcium ruthenium oxide, and the second upper electrode film comprises an alloy of iridium and ruthenium, an alloy of iridium and platinum, an alloy of iridium and palladium, an alloy of ruthenium and platinum, an alloy of ruthenium and palladium and/or an alloy of platinum and palladium.

16. The ferroelectric structure of claim 13, wherein the second upper electrode film comprises about 30 to about 50 percent by weight of iridium and about 50 to about 70 percent by weight of ruthenium.

17. The ferroelectric structure of claim 13, further comprising:
an insulation structure covering the lower structure; and
an adhesion layer between the insulation structure and the first lower electrode film, wherein the adhesion layer comprises titanium, tantalum, aluminum, tungsten, titanium nitride, tantalum nitride, aluminum nitride and/or tungsten nitride.

18. The ferroelectric structure of claim 1 further comprising:
a substrate having a contact region;
at least one insulation layer on the substrate; and
at least one pad electrically connected to the contact region through the insulation layer;
wherein the lower electrode is disposed on the pad and the insulation layer.

19. The ferroelectric structure of claim 18, wherein the first metal oxide and the first alloy are substantially the same as the second metal oxide and the second alloy, respectively.

20. The ferroelectric structure of claim 18, wherein the first upper electrode film comprises indium tin oxide, iridium oxide, strontium ruthenium oxide, strontium titanium oxide, lanthanum nickel oxide and/or calcium ruthenium oxide, and the second upper electrode film comprises an alloy of iridium and ruthenium, an alloy of iridium and platinum, an alloy of iridium and palladium, an alloy of ruthenium and platinum, an alloy of ruthenium and palladium and/or an alloy of platinum and palladium.

21. The ferroelectric structure of claim 18, wherein the second upper electrode film comprises about 30 to about 50 percent by weight of iridium and about 50 to about 70 percent by weight of ruthenium.

22. The ferroelectric structure of claim 18, further comprising an adhesion layer formed between the insulation layer and the first lower electrode film wherein the adhesion layer includes a second metal and/or a second metal nitride.

23. A ferroelectric structure comprising:
a lower electrode including titanium aluminum nitride and iridium;
a ferroelectric layer on the lower electrode, wherein the ferroelectric layer includes PZT; and
an upper electrode on the ferroelectric layer, wherein the upper electrode comprises strontium ruthenium oxide and an alloy including about 30 to about 50 percent by weight of iridium and about 50 to about 70 percent by weight of ruthenium.

24. The ferroelectric structure of claim 23, wherein the lower electrode comprises:
a first lower electrode film including titanium aluminum nitride; and
a second lower electrode film on the first lower electrode film, the second lower electrode film including iridium.

25. The ferroelectric structure of claim 24, further comprising an adhesion layer beneath the first lower electrode film wherein the adhesion layer includes titanium.

26. The ferroelectric structure of claim 23, wherein the upper electrode comprises:
a first upper electrode film on the ferroelectric layer, the first upper electrode film including strontium ruthenium oxide; and
a second upper electrode film on the first upper electrode film, the second upper electrode film including the alloy of iridium and ruthenium.

27. The ferroelectric structure of claim 23 further comprising:
a substrate; and
a lower structure on the substrate;
wherein the lower electrode is electrically connected to the lower structure to provide a ferroelectric capacitor.

28. The ferroelectric structure of claim 27, wherein the lower electrode comprises:
a first lower electrode film pattern electrically connected to the lower electrode, the first lower electrode film pattern including titanium aluminum nitride; and
a second lower electrode film pattern on the first lower electrode film pattern, the second lower electrode film pattern including iridium.

29. The ferroelectric structure of claim 28, further comprising:
an insulation structure covering the lower structure; and
an adhesion layer pattern between the insulation structure and the first lower electrode film pattern, the adhesion layer pattern including titanium

30. The ferroelectric structure of claim 27, wherein the upper electrode comprises:
a first upper electrode film pattern on the ferroelectric layer, the first upper electrode film pattern including strontium ruthenium oxide; and
a second upper electrode film pattern on the first upper electrode film pattern, the second upper electrode film pattern including the alloy of iridium and ruthenium.

31. A method of forming a ferroelectric structure comprising:
forming a first lower electrode film using a first metal nitride;
forming a second lower electrode film on the first lower electrode film using a first metal, a first metal oxide and/or a first alloy;
forming a ferroelectric layer on the second lower electrode film;
forming a first upper electrode film on the ferroelectric layer using a second metal oxide; and
forming a second upper electrode film on the first upper electrode film using a second alloy.

32. The method of claim 31, wherein the first lower electrode film is formed by an electron-beam (E-beam) evaporation process, a sputtering process, a chemical vapor deposition (CVD) process, an atomic layer deposition (ALD) process and/or a pulse laser deposition (PLD) process.

33. The method of claim 31, wherein the ferroelectric layer is formed by a sol-gel process, an MOCVD process, an ALD process, a liquid phase epitaxy (LPE) process and/or a PLD process.

34. The method of claim 31, wherein the first upper electrode film is formed by an E-beam evaporation process, a sputtering process, a CVD process, an ALD process and/or a PLD process.

35. The method of claim 31, wherein the second upper electrode film is formed by a sputtering process.

36. The method of claim 35, wherein the second upper electrode film is formed by simultaneously sputtering iridium and ruthenium onto the first upper electrode film from an iridium target and a ruthenium target.

37. The method of claim 35, wherein the second upper electrode film is formed by sputtering an alloy of iridium and ruthenium onto the first upper electrode film from a target including iridium and ruthenium.

38. The method of claim 31, further comprising thermally treating the first and the second upper electrode films.

39. The method of claim 38, wherein the first and the second upper electrode films are thermally treated at about 500° C. to about 700° C. for about 30 seconds to 2 minutes under an atmosphere that includes an oxygen gas, a nitrogen gas or a mixture gas of oxygen and nitrogen.

40. The method of claim 31:
wherein forming the first lower electrode film is preceded by forming a lower structure on a substrate and wherein forming the first lower electrode film comprises forming the first lower electrode film electrically connected to the lower structure using the first metal nitride; and
wherein forming the second upper electrode film is followed by etching the second upper electrode film, the first upper electrode film, the ferroelectric layer, the second lower electrode film and the first lower electrode film to form a lower electrode, a ferroelectric layer pattern and an upper electrode, and thereby form a ferroelectric capacitor.

41. The method of claim 40, wherein the second upper electrode film is formed by simultaneously sputtering iridium and ruthenium onto the first upper electrode film from an iridium target and a ruthenium target.

42. The method of claim 40, wherein the second upper electrode film is formed by sputtering an alloy of iridium and ruthenium onto the first upper electrode film from a target including iridium and ruthenium.

43. The method of claim 40, further comprising thermally treating the first and the second upper electrode films by a rapid thermal process.

44. The method of claim 31 wherein forming the first lower electrode film is preceded by:
forming a contact region on a substrate;
forming at least one insulation layer on the substrate; and
forming at least one pad electrically connected to the contact region through the insulation layer;
wherein forming the first lower electrode film comprises forming the first lower electrode film on the pad and the insulation layer using the first metal nitride; and
wherein forming the second upper electrode film is followed by etching the second upper electrode film, the first upper electrode film, the ferroelectric layer, the second lower electrode film and the first lower electrode film to form a lower electrode, a ferroelectric layer pattern and an upper electrode.

45. The method of claim 44, wherein the second upper electrode film is formed by simultaneously sputtering iridium and ruthenium onto the first upper electrode film from an iridium target and a ruthenium target, or by sputtering an alloy of iridium and ruthenium onto the first upper electrode film from a target including iridium and ruthenium.

46. The method of claim 44, further comprising thermally treating the first and the second upper electrode films by a rapid thermal process.
